(19) United States
(12) Patent Application Publication
(10) Pub. No.: US 2026/0161502 A1
(43) Pub. Date: Jun. 11, 2026

(54) ECC CIRCUIT, OPERATION METHOD OF ECC CIRCUIT, AND STORAGE CONTROLLER INCLUDING ECC CIRCUIT

(71) Applicant: Samsung Electronics Co., Ltd., Suwon-si (KR)

(72) Inventors: Kijun Jeon, Suwon-si (KR); YongSung Kil, Suwon-si (KR); Kyoungbin Park, Suwon-si (KR); Min-Ki Song, Suwon-si (KR); Dong-Min Shin, Suwon-si (KR); Dae-Yeol Yang, Suwon-si (KR); Daeyoung Yun, Suwon-si (KR); Bohwan Jun, Suwon-si (KR)

(21) Appl. No.: 19/265,973

(22) Filed: Jul. 10, 2025

(30) Foreign Application Priority Data
Dec. 10, 2024 (KR) 10-2024-0182374

(51) Int. Cl. G06F 11/10

(52) U.S. Cl. CPC G06F 11/1044

(57) ABSTRACT

An example error correction code (ECC) circuit includes an ECC decoder, and the ECC decoder includes a first decoder that performs a virtual puncturing operation for setting an initial bit value of bits of a superposition region in a read codeword received from an outside to a first value to generate a punctured codeword and performs a first sub-ECC decoding on the punctured codeword to generate a first estimated codeword, a reconstructed data generator that generates a second estimated codeword corresponding to the superposition region based on the read codeword and the first estimated codeword and generates a reconstructed codeword including read information data, main parity data, and first sub-parity data based on the read codeword and the second estimated codeword, and a second decoder that performs main ECC decoding on the reconstructed codeword together with the first decoder to correct an error in the reconstructed codeword.

### CROSS-REFERENCE TO RELATED APPLICATION

This application claims priority under 35 U.S.C. § 119 to Korean Patent Application No. 10-2024-0182374 filed on Dec. 10, 2024, in the Korean Intellectual Property Office, the disclosures of which are incorporated by reference herein in their entireties.

### BACKGROUND

A semiconductor memory is classified as a volatile memory, in which stored data disappear when a power is turned off, such as a static random access memory (SRAM) or a dynamic random access memory (DRAM), and a nonvolatile memory, in which stored data are retained even when a power is turned off, such as a flash memory, a phase-change RAM (PRAM), a magnetic RAM (MRAM), a resistive RAM (RRAM), or a ferroelectric RAM (FRAM).

A storage device including a semiconductor memory includes an error correction code (ECC) circuit for improving reliability of stored data. The ECC circuit encodes input data and outputs write data including parity bits. As the number of parity bits increases, the reliability of the input data may increase. However, when the number of parity bits is excessively increased, the capacity occupied by input data in write data may decrease. Therefore, it is desired to provide an ECC circuit that generates write data including many parity bits without reducing the capacity of the input data.

### SUMMARY

The present disclosure relates to an ECC circuit having improved performance, an operating method of the ECC circuit, and a storage controller including the ECC circuit.

In some implementations, an ECC circuit includes an ECC decoder, and the ECC decoder includes a first decoder that performs a virtual puncturing operation for setting an initial bit value of bits of a superposition region in a read codeword received from an external device to a first value to generate a punctured codeword and performs a first sub-ECC decoding on the punctured codeword to generate a first estimated codeword, a reconstructed data generator that generates a second estimated codeword corresponding to the superposition region based on the read codeword and the first estimated codeword and generates a reconstructed codeword including read information data, main parity data, and first sub-parity data based on the read codeword and the second estimated codeword, and a second decoder that performs main ECC decoding on the reconstructed codeword together with the first decoder to correct an error in the reconstructed codeword.

In some implementations, a storage controller includes an ECC circuit, the ECC circuit includes an ECC decoder including a first decoder and a reconstructed data generator, and the first decoder performs a virtual puncturing operation for setting an initial log-likelihood ratio (LLR) corresponding to information bits included in a superposition region of a read codeword received from a nonvolatile memory device to a first LLR value to generate a virtual punctured codeword and performs a first sub-ECC (error correction code) decoding on the virtual punctured codeword to generate a first estimated codeword, and the reconstructed data generator generates a second estimated codeword by removing an element of the first estimated codeword from the read codeword, performs a second sub-ECC decoding on the second estimated codeword to generate a read free-riding codeword, generates a main read codeword including main read parity data by removing an element of the read free-riding codeword from the read codeword, obtains first sub-read parity data based on the read free-riding codeword, and generates a reconstructed codeword by combining the main read codeword and the first sub-read parity data.

In some implementations, an operation method of an ECC circuit including an ECC decoder, includes receiving, by the ECC decoder, a read codeword, performing, by the ECC decoder, a virtual puncturing operation for setting an initial log-likelihood ratio (LLR) corresponding to a superposition region included in the read codeword to a first LLR value, performing, by the ECC decoder, a first sub-ECC decoding on a virtual punctured codeword generated as a result of performing the virtual puncturing operation to generate a first estimated codeword, generating, by the ECC decoder, a second estimated codeword based on the read codeword and the first estimated codeword, performing, by the ECC decoder, a second sub-ECC decoding on the second estimated codeword to obtain a read free-riding codeword, generating, by the ECC decoder, a main read codeword including main read parity data based on the read codeword and the read free-riding codeword, obtaining, by the ECC decoder, a first sub-read parity data based on the read free-riding codeword, and generating, by the ECC decoder, a reconstructed codeword by combining the first main read codeword and the first sub-read parity data.

### BRIEF DESCRIPTION OF THE DRAWINGS

The above and other objects and features of the present disclosure will become apparent by describing in some implementations thereof with reference to the accompanying drawings.

FIG. 1 is a block diagram illustrating an example of a storage device.

FIG. 2 is a block diagram illustrating an example of a storage controller of FIG. 1.

FIGS. 3A and 3B are diagrams for describing an example low density parity check (LDPC) decoding.

FIG. 4 is a diagram for describing an example of ECC encoding of an ECC encoder of FIG. 1.

FIG. 5A is a block diagram illustrating an example of an ECC encoder of FIG. 1.

FIG. 5B is a flowchart for describing an example of an operation method of an ECC encoder of FIG. 1.

FIGS. 6A, 6B, and 6C are diagrams for describing an example of an operation of an ECC encoder of FIG. 1.

FIG. 7 is a flowchart for describing an example of an operation of an ECC decoder of FIG. 1.

FIG. 8A is a block diagram illustrating an example of an ECC decoder of FIG. 1.

FIG. 8B is a flowchart for describing an example operation S220 of FIG. 7.

FIG. 9 is a diagram for describing example operations S221 and S222 of FIG. 8B.

FIG. 10A and FIG. 10B are diagrams for describing an example of a virtual puncturing operation and an example of a first sub-ECC decoding of FIG. 9.

FIG. 11 is a diagram for describing example operations S223 and S224 of FIG. 8B.

FIG. 12 is a diagram for describing an example operation S225 of FIG. 8B.

FIG. 13 is a diagram for describing example operations S226 and S227 of FIG. 8B.

FIG. 14 is a block diagram illustrating an example of a first decoder of FIG. 8A.

FIG. 15 is a block diagram illustrating an example of a reconstructed codeword generator of FIG. 8A.

FIG. 16 is a block diagram illustrating an example of a storage device.

FIG. 17 is a block diagram illustrating an example of a storage device.

FIG. 18 is a diagram illustrating an example of a system to which a storage device.

### DETAILED DESCRIPTION

Hereinafter, implementations of the present disclosure may be described in detail and clearly to such an extent that an ordinary one in the art easily implements the present disclosure.

In the detailed description, components or function blocks corresponding to terms such as “block”, “unit”, “logic”, etc. may be implemented in the form of software, hardware, or a combination thereof.

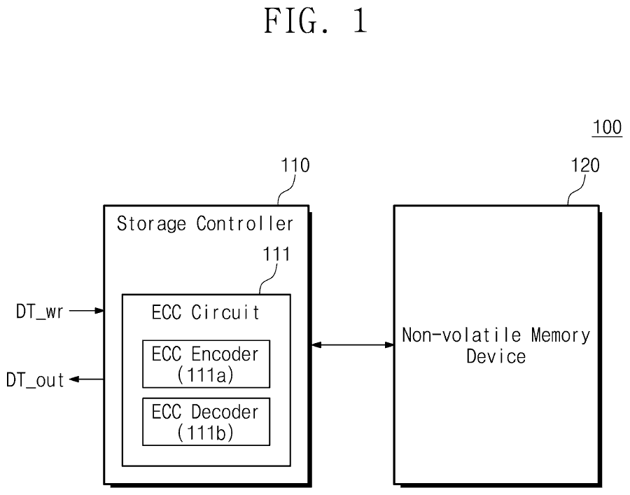

FIG. 1 is a block diagram illustrating an example of a storage device. Referring to FIG. 1, a storage device 100 may include a storage controller 110 and a nonvolatile memory device 120. In some implementations, the storage device 100 may be a large-capacity storage medium such as a solid state drive SSD. The storage device 100 may be included in one of the information processing devices configured to process various information and to store processed information, such as a personal computer, a laptop, a server, a workstation, a smartphone, a tablet PC, a digital camera, a black box, etc. However, the scope of the present disclosure is not limited thereto, and the storage device 100 may be implemented in various forms and may be included in various devices or various systems.

The storage controller 110 may be configured to control the nonvolatile memory device 120. The storage controller 110 may store data in the nonvolatile memory device 120 or may read data stored in the nonvolatile memory device 120 under control of an external host device. The storage controller 110 may transmit a command or an address to the nonvolatile memory device 120 to store data in the nonvolatile memory device 120 or read data stored in the nonvolatile memory device 120.

The nonvolatile memory device 120 may operate under control of the storage controller 110. For example, the nonvolatile memory device 120 may store data or output stored data under the control of the storage controller 110. In some implementations, the nonvolatile memory device 120 may be a NAND flash memory, but the scope of the present disclosure is not limited thereto.

In some implementations, the storage controller 110 may include an ECC (Error Correction Code) circuit 111. The ECC circuit 111 may include an ECC encoder 111a and an ECC decoder 111b. The ECC encoder 111a may encode write data DT_wr received from an external host device to generate a write codeword. For example, the write data DT_wr may be composed of information bits. The ECC encoder 111a may perform main ECC encoding on the write data DT_wr to generate a main write codeword including the write data DT_wr and main write parity data. The main write parity data may include parity bits for correcting an error of the write data DT_wr.

The ECC encoder 111a may perform first sub-ECC encoding on the sub-write data included in the write data DT_wr to generate first sub-write parity data. The first sub-write parity data may be composed of first sub-parity bits for correcting an error of the sub-write data. The ECC encoder 111a may perform second sub-ECC encoding on the first sub-write parity data to generate second sub-write parity data. The second sub-write parity data may be composed of second sub-parity bits for correcting an error of the first sub-write parity data.

The ECC encoder 111a may generate a write free-riding codeword by combining the first sub-write parity data and the second sub-write parity data. The ECC encoder 111a may generate a main write codeword by combining the write data DT_wr and the main write parity data. The ECC encoder 111a may generate a write codeword by superpositioning the write free-riding codeword on the main write codeword. Accordingly, the write codeword may include elements of the write data DT_wr, the main write parity data, and the first sub-write parity data. The ECC encoder 111a may transmit the write codeword to the nonvolatile memory device 120. The nonvolatile memory device 120 may store the write codeword.

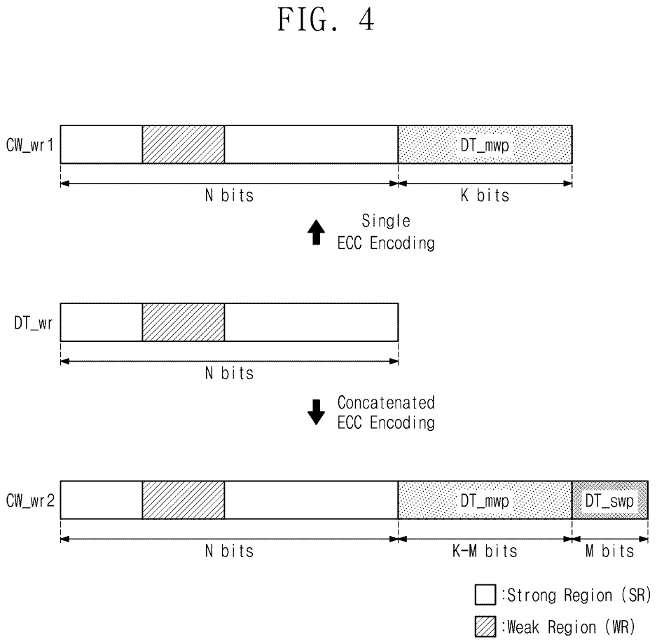

As described above, the ECC encoder 111a may generate a write codeword including elements of the write data DT_wr, the main write parity data, and the first sub-write parity data without increasing a total number of bits of the write codeword (i.e., a size of the write codeword). That is, the ECC encoder 111a may free-ride the write free-riding codeword on the main write data so as to be transmitted to the nonvolatile memory device 120. A detail operation of the ECC encoder 111a will be described in more detail with reference to FIGS. 4 to 6C.

The ECC decoder 111b may generate output data DT_out based on the read codeword received from the nonvolatile memory device 120. For example, the read codeword may be data encoded by the ECC encoder 111a and stored in the nonvolatile memory device 120. That is, as described above, for example, the read codeword may be data generated by superpositioning the read free-riding codeword on the main read codeword.

The ECC decoder 111b may perform a first sub-ECC decoding to generate a first estimated codeword. The first estimated codeword may include an estimation result for bit values of information bits corresponding to a superposition region of the read codeword. The ECC decoder 111b may generate a second estimated codeword based on the read codeword and the first estimated codeword. The ECC decoder 111b may perform a second sub-ECC decoding on the second estimated codeword to obtain a read free-riding codeword. The ECC decoder 111b may obtain a main read codeword based on the read codeword and the read free-riding codeword. The main read codeword may include read information data including information bits and main read parity data.

The ECC decoder 111b may obtain the first sub-read parity data based on the read free-riding codeword. The ECC decoder 111b may generate a reconstructed codeword by combining the main read codeword and the first sub-read parity data.

The ECC decoder 111b may perform main ECC decoding on the reconstructed codeword to generate a corrected reconstructed codeword. The storage controller 110 may transmit information bits excluding parity bits of the corrected reconstructed codeword to an external host device as the output data DT_out.

For example, the read information data may be N-bit data, the main read parity data may be K-bit data, and the first sub-read parity data may be M-bit data (where, “N”, “K”, and “M” are positive integers). Accordingly, the reconstructed codeword may be N+K+M bit data, and K+M bits in the reconstructed codeword may be parity data (e.g., including main read parity data and first sub-read parity data).

Meanwhile, the read codeword may be composed of N+K bits. In other words, the ECC decoder 111b may obtain parity data composed of K+M bit parity bits for correcting an error in the read information data composed of N bit information bits from the N+K bit read codeword. Accordingly, the error correction capability of the ECC decoder 111b may be improved compared to an ECC decoder that performs error correction based on K bit parity data.

As described above, the ECC circuit 111 may generate a write codeword by superpositioning a write free-riding codeword including the first sub-write parity data on the main write codeword. Accordingly, the ECC circuit 111 may generate the write codeword including additional parity data (i.e., the first sub-write parity data) without reducing the size (i.e., number of bits) of the main parity data. In addition, the ECC circuit 111 may obtain a main read codeword including the main read parity data and the first sub-read parity data from the read codeword received from the nonvolatile memory device 120. The ECC circuit 111 may generate reconstructed data based on the main read codeword and the first sub-read parity data, and may perform error correction on the reconstructed data. Accordingly, the ECC circuit 111 may have an improved error correction capability without increasing the data size (i.e., total number of bits) of the write codeword.

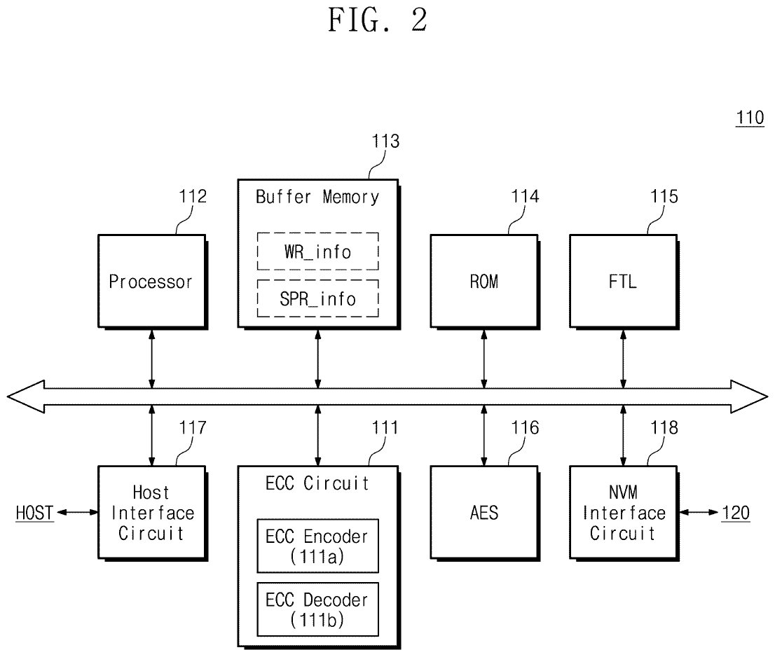

FIG. 2 is a block diagram illustrating an example of a storage controller of FIG. 1. Referring to FIGS. 1 and 2, the storage controller 110 may include the ECC circuit 111, a processor 112, a buffer memory 113, a read only memory (ROM) 114, a flash translation layer (FTL) 115, an advanced encryption standard (AES) engine 116, a host interface circuit 117, and a nonvolatile memory interface circuit 118.

The ECC circuit 111 may generate a write codeword based on write data DT_wr as described above with respect to FIG. 1. In addition, the ECC circuit 111 may generate a reconstructed codeword based on a read codeword received from the nonvolatile memory device 120, and may perform ECC decoding on the reconstructed codeword to generate the output data DT_out. The operation of the ECC circuit 111 will be described in more detail with reference to the drawings below.

The processor 112 may control overall operations of the storage controller 110. For example, the processor 112 may execute various applications running on the storage controller 110.

The buffer memory 113 may be configured to store various information required for the operation of the storage controller 110. The buffer memory 113 may temporarily store write data to be stored in the nonvolatile memory device 120 or read data read from the nonvolatile memory device 120. For example, the buffer memory 113 may be implemented as a static random access memory (SRAM), a dynamic random access memory (DRAM), etc. In some implementations, the buffer memory 113 may store weak region information WR_info and superposition region information SPR_info used for ECC encoding and ECC decoding of the ECC circuit 111. In some implementations, the weak region information WR_info may include information on the position of data corresponding to the sub-parity data. In some implementations, the superposition region information SPR_info may include information about the position where the write free-riding codeword superposes and the position where the read free-riding codeword superposes.

The ROM 114 may be used as a read-only memory that stores information necessary for the operation of the storage controller 110. For example, the ROM 114 may be used as a part of the firmware memory.

The FTL 115 may perform a role of mapping a logical address received from a host device HOST to a physical address used in the nonvolatile memory device 120. The FTL 115 may perform a maintenance operation for efficiently managing or using the nonvolatile memory device 120. In some implementations, the maintenance operation may include an address mapping operation, a wear-leveling operation, and a garbage collection operation.

The AES engine 116 may perform at least one of an encryption operation and a decryption operation on data input to the storage controller 110, using a symmetric key algorithm.

The host interface circuit 117 may communicate with the external host HOST based on a host interface. In some implementations, the host interface may include at least one of various interfaces, such as an Advanced Technology Attachment (ATA), a Serial ATA (SATA), an external SATA (e-SATA), a Small Computer Small Interface (SCSI), a Serial Attached SCSI (SAS), a Peripheral Component Interconnection (PCI), a PCIe (PCI express), an NVMe (NVM express), an IEEE 1394, a universal serial bus (USB), a secure digital (SD) card, a multi-media card (MMC), an embedded multi-media card (eMMC), a Universal Flash Storage (UFS), an embedded Universal Flash Storage (eUFS), and/or a compact flash (CF) card.

The nonvolatile memory interface circuit 118 may communicate with the nonvolatile memory device 120 based on the memory interface. In some implementations, the memory interface may include one of interfaces, such as Toggle or Open NAND Flash Interface (ONFI).

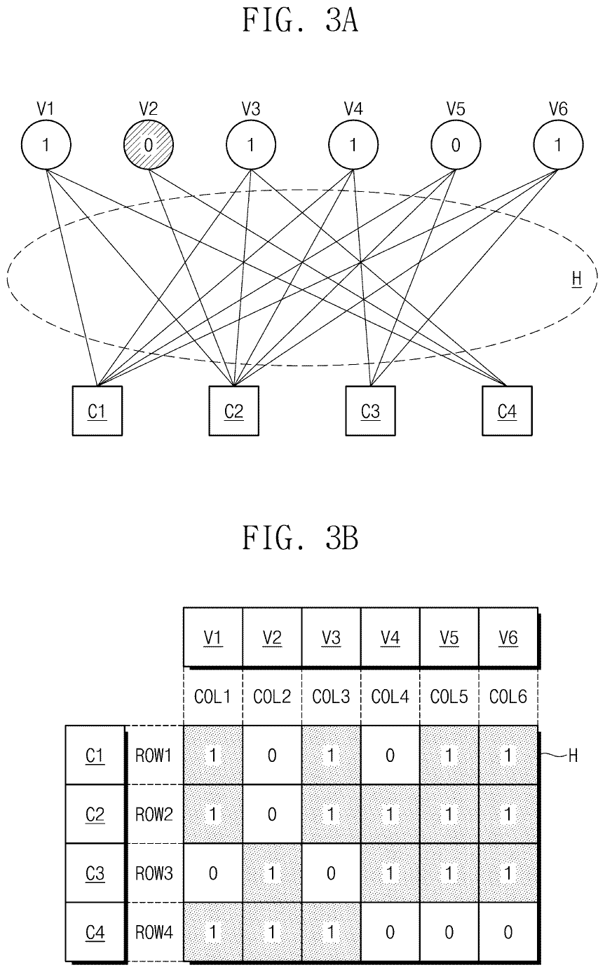

FIGS. 3A and 3B are diagrams for describing an example LDPC decoding. FIG. 3A illustrates LDPC decoding expressed as a tanner graph, and FIG. 3B is a diagram illustrating a parity check matrix “H” of FIG. 3A.

Referring to FIG. 3A, an LDPC decoder performing LDPC decoding may include a plurality of variable nodes V1 to V6 and a plurality of check nodes C1 to C4. For example, the LDPC decoder may store a read codeword received from the nonvolatile memory device (e.g., 120 of FIG. 1) in the variable nodes V1 to V6.

For example, the LDPC decoder may calculate initial LLRs (Log-Likelihood Ratios) corresponding to each bit of the read codeword and may store the read data (e.g., the read codeword) in the variable nodes V1 to V6. The LLR may be a value obtained by taking the logarithm of the probability that a specific bit is “0” divided by the probability that a specific bit is “1”.

For example, the LDPC decoder may perform LDPC decoding based on hard decision. In this case, when the bit value of the bit corresponding to a variable node is “0”, the LDPC decoder may store the positive LLR as the initial LLR of the corresponding variable node, and when the bit value is “1”, may store the negative LLR as the initial LLR of the corresponding variable node. In this case, the absolute values (i.e., magnitudes) of the positive LLR and the negative LLR may be the same.

For example, the LDPC decoder may perform LDPC decoding based on soft decision. In this case, when the bit value of the bit corresponding to a variable node is “0”, the LDPC decoder may store the positive LLR as the initial LLR of the corresponding variable node, and when the bit value is “1”, may store the negative LLR as the initial LLR of the corresponding variable node. In this case, the size of the LLR stored in the variable node may vary depending on the reliability of the bit value of the bit corresponding to the variable node.

For example, as illustrated in FIG. 3A, the read codeword may be “101101”. In this case, the LDPC decoder performing hard decision-based LDPC decoding may store the initial LLR “−5” in the variable nodes V1, V3, V4, and V6 and may store the initial LLR “5” in the variable nodes V2 and V5. Accordingly, the LDPC decoder may store the read codeword in the variable nodes V1 to V6.

The variable nodes V1 to V6 may be connected to the check nodes C1 to C4 based on the information of the parity check matrix “H”. The check nodes C1 to C4 may check whether the bits stored in the variable nodes V1 to V6 satisfy an error detection rule. The bit value of the bit stored in the variable node that does not satisfy the error detection rule may be changed.

As illustrated in FIG. 3A, the bit information of the read codeword may be “101101”. Accordingly, the bit information stored in the variable nodes V1 to V6 may be “101101”. Each of the check nodes C1 to C4 may check whether the error detection rule that makes the sum of the bits of the connected variable nodes an even number is satisfied.

The first check node C1 may be connected to the variable nodes V1, V3, V4, V5, and V6. The sum of the bit values of the variable nodes V1, V3, V4, V5, and V6 connected to the first check node C1 may be an even number. The second check node C2 may be connected to the variable nodes V1, V2, V3, V4, V5, and V6. The sum of the bit values of the variable nodes V1, V2, V3, V4, V5, and V6 connected to the second check node C2 may be an even number. The third check node C3 may be connected to the variable nodes V4, V5, and V6. The sum of bit values of the variable nodes V4, V5, and V6 connected to the third check node C3 may be an even number. The fourth check node C4 may be connected to the variable nodes V1, V2, and V3. The sum of bit values of the variable nodes V1, V2, and V3 connected to the fourth check node C4 may be an even number. In this case, the ECC decoder may determine that there is no error in the read codeword and may output data having the same bit information as the read codeword.

The variable node and the check node may be connected through an edge. The variable nodes V1 to V6 may transmit variable node messages containing information associated with the current bit value (i.e., the LLR) to the check nodes C1 to C4 through connected edges. The check nodes C1 to C4 may transmit check node messages containing information associated with whether the error detection rule is satisfied to the variable nodes V1 to V6. The variable nodes V1 to V6 and the check nodes C1 to C4 may determine whether the error detection rule is satisfied and may correct errors in the read codeword through repeated message exchange. For example, the LDPC decoder may correct errors in the read codeword by changing the LLR of the variable nodes V1 to V6 based on the check node message.

Meanwhile, the more check nodes connected to a variable node, the more judgments may be performed about whether the error detection rule is satisfied. Therefore, as the number of check nodes connected to the variable node increases, the error correction capability of the LDPC decoder for the variable node may be improved. In the case of FIG. 3A, the second variable node V2 may be connected to only two check nodes C2 and C4. Each of the variable nodes V1, V3, V4, V5, and V6 may be connected to three check nodes. Accordingly, the LDPC decoder may have a lower error correction capability with respect to the second variable node V2 compared to the other variable nodes V1, V3, V4, V5, and V6. In other words, the probability of error correction success for the second variable node V2 may be lower than the probability of error correction success for the other variable nodes V1, V3, V4, V5, and V6.

Referring to FIG. 3B, each of the elements included in the parity check matrix “H” may have a value of “1” when there is a connection between the variable node and the check node, and a value of “0” when there is no connection. For example, the elements of the second row and the third column of the parity check matrix “H” may have the value of “1”. In this case, the second check node C2 and the third variable node V3 may be connected. The element of the third row and the first column of the parity check matrix “H” may have the value of “0”. In this case, the third check node C3 may not be connected to the first variable node V1.

That is, the number of elements having a value of “1” in each column of the parity check matrix “H” may represent the number of check nodes connected to the variable node corresponding to each column. In other words, the number of elements having a value of “1” in each column may represent the error correction capability of the LDPC decoder for the variable node corresponding to each column. In this case, as the number of elements having a value of “1” in the column of the parity check matrix “H” corresponding to the variable node increases, the error correction capability of the LDPC decoder for the variable node may be improved.

Meanwhile, FIG. 3B only illustrates an example of the parity check matrix “H”, and the present disclosure is not limited thereto.

In some implementations, the ECC decoder 111b of FIG. 1 may perform LDPC decoding in a manner similar to that described above through FIGS. 3A and 3B to generate the output data DT_out.

FIG. 4 is a diagram for describing an example of ECC encoding of an ECC encoder of FIG. 1. FIG. 4 is described with reference to FIG. 1 to FIG. 3B. Referring to FIG. 4, the ECC encoder 111a may receive the write data DT_wr of N bits from an external host device. For example, the ECC encoder 111a may perform a single ECC encoding on the write data DT_wr to generate a first write codeword CW_wr1 of N+K bits. The single ECC encoding may be LDPC encoding based on an LDPC code.

For example, the ECC encoder 111a may perform the LDPC encoding on the write data DT_wr to generate the first write codeword CW_wr1 of N+K bits. The result of performing a matrix multiplication calculation with the first write codeword CW_wr1 and the parity check matrix “H” may satisfy “0”. The first write codeword CW_wr1 may include the write data DT_wr including N bits of information bits and main write parity data DT_mwp including K bits of main parity bits. That is, the LDPC encoding may be understood as a calculation of solving a simultaneous equation defined by the parity check matrix “H” to find the values of bits of the unknown main write parity data DT_mwp based on the write data DT_wr.

Meanwhile, the write data DT_wr may include a strong region SR and a weak region WR. The weak region WR may mean a region where the probability of error correction success through LDPC decoding is lower than that of the strong region SR (i.e., a region where the error correction capability of the LDPC decoder is low). That is, the information bits in the weak region WR may have a smaller number of elements having a value of “1” in the column of the corresponding parity check matrix “H” compared to the information bits in the strong region SR. In some implementations, a difference between the number of elements having a value of “1” included in the column corresponding to the information bits of the weak region WR in the parity check matrix “H” and the number of elements having a value of “1” included in the column corresponding to the information bits of the strong region SR may be greater than or equal to a predetermined reference number. For example, when an error occurs in the information bits of the weak region WR, error correction may fail even if the LDPC decoding is performed on the first write codeword CW_wr1.

Therefore, to solve the above-described problem, for example, the ECC encoder 111a may perform concatenated ECC encoding on the write data DT_wr to generate a second write codeword CW_wr2. In detail, the ECC encoder 111a may perform main ECC encoding (e.g., the LDPC encoding) on the write data DT_wr to generate the main write parity data Dt_mwp of K bits. In addition, the ECC encoder 111a may perform sub-ECC encoding (e.g., hamming code-based encoding) on the data of the weak region WR of the write data DT_wr to generate sub-write parity data DT_swp of M bits.

The ECC encoder 111a may combine the write data DT_wr, the main write parity data DT_mwp, and the sub-write parity data DT_swp to generate the second write codeword CW_wr2 of N+K+M bits. In this case, the ECC encoder 111a may strengthen the protection of the data in the weak region WR by generating the sub-write parity data DT_swp to correct errors in the data in the weak region WR.

However, unlike as illustrated in FIG. 4, one codeword may be composed of only N+K bits. Therefore, even when performing concatenated ECC encoding on the write data DT_wr of N bits, the second write codeword CW_wr2 may be configured not to include parity bits exceeding K bits. Therefore, when performing concatenated ECC encoding, the ECC encoder 111a may have to generate main write parity data DT_mwp having a smaller number of bits than when performing only LDPC encoding. For example, the ECC encoder 111a may generate the sub-write parity data DT_swp composed of M-bit sub-parity bits. In this case, the ECC encoder 111a may need to generate the main write parity data DT_mwp composed of main parity bits of K-M bits. Accordingly, the number of parity bits for LDPC decoding may be reduced compared to the case of performing single ECC encoding.

In LDPC decoding, the number of parity bits may be the same as the number of rows of the parity check matrix “H”. Therefore, when the number of main write parity bits is reduced, the protection for data in the strong region SR through LDPC decoding may be weakened (i.e., the probability of error correction success through LDPC decoding may be reduced).

The ECC encoder 111a according to some implementations of the present disclosure may generate a write codeword by superpositioning a write-free riding codeword on a main write codeword of N+K bits including the main write parity data DT_mwp of K bits such as the first write codeword CW_wr1. The write-free riding codeword may include the sub-write parity data DT_swp. Accordingly, the ECC encoder 111a may strengthen the protection of data in the weak region WR without reducing the number (“K”) of bits of the main write parity data DT_mwp (i.e., while maintaining the protection for the strong region SR).

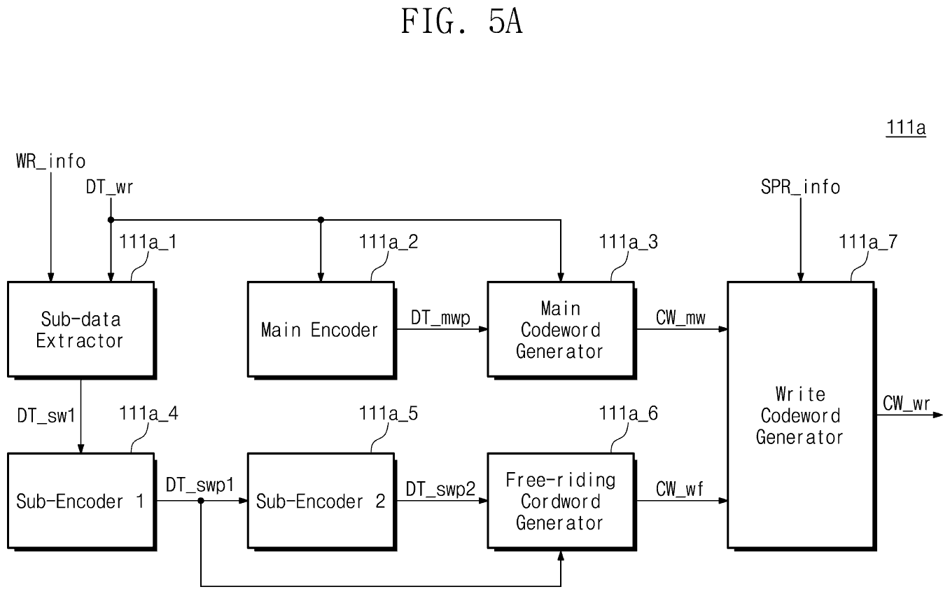

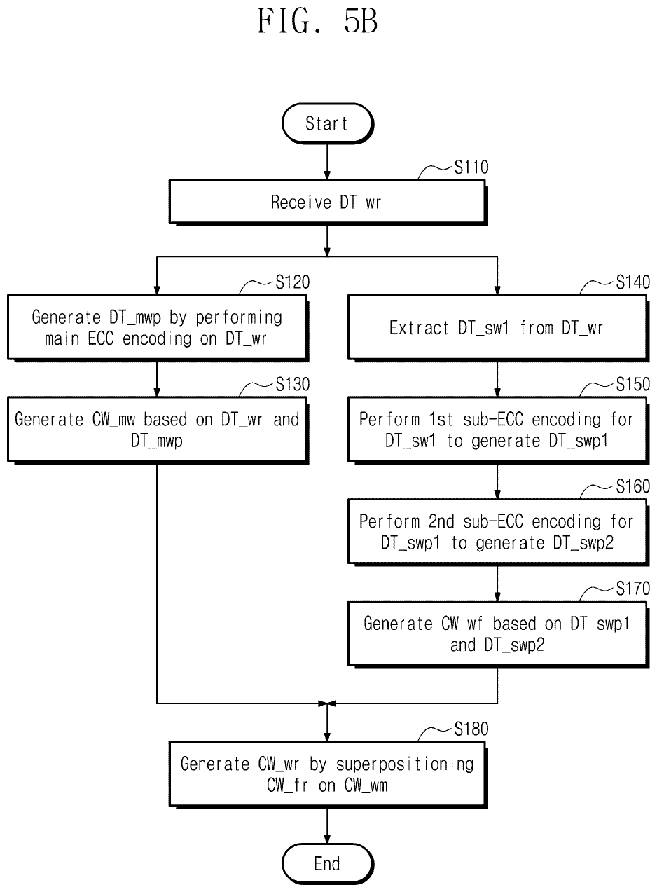

FIG. 5A is a block diagram illustrating an example of an ECC encoder of FIG. 1, and FIG. 5B is a flowchart for describing an example of an operation method of an ECC encoder of FIG. 1. FIGS. 5A and 5B are described with reference to FIGS. 1 and 2. Referring to FIG. 5A, the ECC encoder 111a may include a sub-data extractor 111a_1, a main encoder 111a_2, a main codeword generator 111a_3, a first sub-encoder 111a_4, a second sub-encoder 111a_5, a free-riding codeword generator 111a_6, and a write codeword generator 111a_7. However, the present disclosure is not limited thereto, and the ECC encoder 111a may be implemented in various ways.

Referring to FIG. 5B, in operation S110, the ECC encoder 111a may receive the write data DT_wr. The ECC encoder 111a may receive the write data DT_wr from the buffer memory 113. For example, the write data DT_wr may be provided from the nonvolatile memory device 120 and may be stored in the buffer memory 113. For example, the sub-data extractor 111a_1 may receive the write data DT_wr and the weak region information WR_info from the buffer memory 113. In addition, the main encoder 111a_2 may receive the write data DT_wr from the buffer memory 113.

In operation S120, the ECC encoder 111a may perform main ECC encoding on the write data DT_wr to generate the main write parity data DT_mwp. For example, the main encoder 111a_2 may perform main ECC encoding on the write data DT_wr based on a first code to generate the main write parity data DT_mwp. In some implementations, the first code may be an LDPC code, and the main ECC encoding may be an LDPC encoding.

In operation S130, the ECC encoder 111a may generate a main write codeword CW_mw based on the write data DT_wr and the main write parity data DT_mwp. For example, the main codeword generator 111a_3 may generate the main write codeword CW_mw by combining the main write parity data DT_mwp and the write data DT_wr.

In operation S140, the ECC encoder 111a may extract first sub-write data DT_sw1 from the write data DT_wr. In detail, the sub-data extractor 111a_1 may identify the position of the weak region WR in the write data DT_wr based on the weak region information WR_info. In some implementations, the weak region information WR_info may include information that bits from an x-th bit to a y-th bit of the write data DT_wr constitute the weak region WR (where, “x” and “y” are positive integers, and “y” is greater than “x”). For example, the weak region information WR_info may be determined in advance. As described above with respect to FIG. 4, the weak region WR may include information bits having a low error correction probability through LDPC decoding. For example, the weak region WR may include information bits having a low error correction probability through ECC decoding based on the main write parity data DT_mwp. The sub-data extractor 111a_1 may extract the first sub-write data DT_sw1 composed of information bits of the weak region WR from the write data DT_wr.

In operation S150, the ECC encoder 111a may perform a first sub-ECC encoding on the first sub-write data DT_sw1 to generate first sub-write parity data DT_swp1. In detail, the first sub-encoder 111a_4 may perform a first sub-ECC encoding on the first sub-write data DT_sw1 based on a second code different from the first code to generate the first sub-write parity data DT_swp1. In some implementations, the second code may be a Hamming code. However, the present disclosure is not limited thereto, and various codes such as a BoseChaudhuri-Hocquenghem (BCH) code, a Reed-Solomon code, etc. may be used as the second code.

In operation S160, the ECC encoder 111a may perform a second sub-ECC encoding on the first sub-write parity data DT_swp1 to generate second sub-write parity data DT_swp2. In detail, the second sub-encoder 111a_5 may perform the second sub-ECC encoding on the first sub-write parity data DT_swp1 based on a third code different from the first code and the second code to generate the second sub-write parity data DT_swp2. In some implementations, the third code may be a Reed-Muller code. In this case, the second sub-encoder 111a_5 may perform a matrix multiplication calculation on a generation matrix generated based on the Reed-Muller code and the first sub-write parity data DT_swp1 to generate the second sub-write parity data DT_swp2. However, the present disclosure is not limited thereto, and various codes for ECC encoding may be used as the third code.

In operation S170, the ECC encoder 111a may generate a write free-riding codeword CW_wf based on the first sub-write parity data DT_swp1 and the second sub-write parity data DT_swp2. For example, the free-riding codeword generator 111a_6 may generate the write free-riding codeword CW_wf by combining the first sub-write parity data DT_swp1 and the second sub-write parity data DT_swp2. In some implementations, the write free-riding codeword CW_wf may be a systematic code.

In operation S180, the ECC encoder 111a may generate a write codeword CW_wr by superpositioning the write free-riding codeword CW_wf on a main write codeword CW_wm. In detail, the write codeword generator 111a_7 may receive the main write codeword CW_wm from the main codeword generator 111a_3, may receive the write free-riding codeword CW_wf from the free-riding codeword generator 111a_6, and may receive the superposition region information SPR_info from the buffer memory 113. The superposition region information SPR_info may include information about a superposition position where the write free-riding codeword CW_wf is superpositioned. For example, the superposition region information SPR_info may be determined in advance.

For example, the superposition region information SPR_info may include information that the bits from a z-th bit to a w-th bit among the bits of the main write codeword CW_wm are included in the superposition position (where, “z” and “w” are positive integers, and “w” is greater than “z”). The write codeword generator 111a_7 may identify the superposition position through the superposition region information SPR_info and may perform a bitwise XOR calculation on the information bits of the superposition position of the main write codeword CW_wm and the bits of the write free-riding codeword CW_wf to generate the write codeword CW_wr.

In some implementations, the bits included in the superposition position may be bits included in the strong region SR described with respect to FIG. 4.

In some implementations, operations S120 and S130 and operations S140 to S170 may be performed in parallel. That is, the ECC encoder 111a may perform the operation of performing the main ECC encoding and generating the main write codeword CW_wm and the operation of extracting the first sub-write data DT_sw1 and performing the first sub-ECC encoding and the second sub-ECC encoding to generate the write free-riding codeword CW_wf in parallel.

In some implementations, unlike as illustrated in FIG. 5A, the ECC encoder 111a may not include the free-riding codeword generator 111a_6. In this case, the second sub-encoder 111a_5 may perform the second sub-ECC encoding to generate the write free-riding codeword CW_wf. The second sub-encoder 111a_5 may transmit the write free-riding codeword CW_wf to the write codeword generator 111a_7. In this case, the write free-riding codeword CW_wf may be a nonsystematic code including elements of the first sub-write parity data DT_swp1 and the second sub-write parity data DT_swp2.

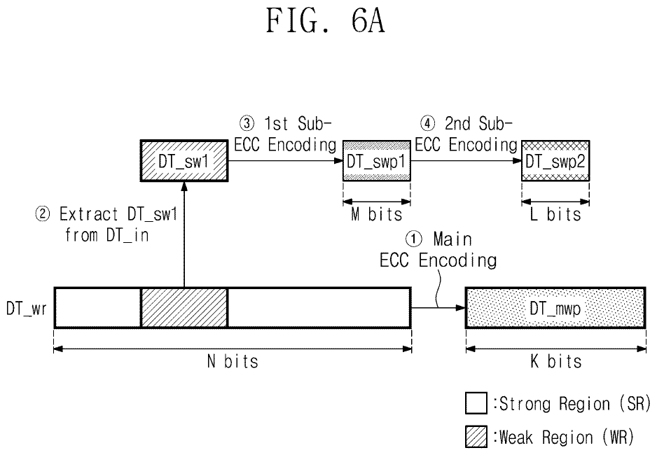

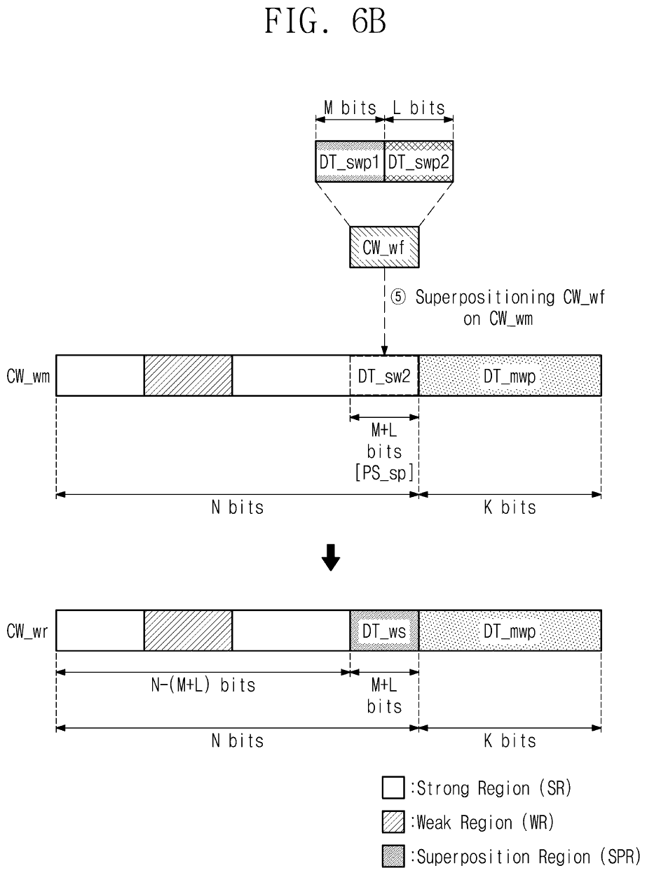

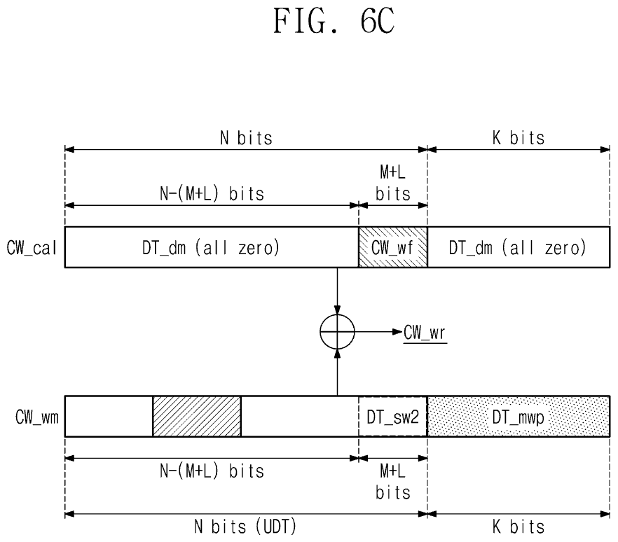

FIGS. 6A, 6B, and 6C are diagrams for describing an example of an operation of an ECC encoder of FIG. 1. FIG. 6A is a diagram for describing operations S110 to S150 of FIG. 5B. FIG. 6B and FIG. 6C are diagrams for describing operation S160 of FIG. 5B. FIG. 6A to FIG. 6C are described with reference to FIG. 1, FIG. 2, FIG. 5A, and FIG. 5B.

Referring to FIG. 6A, in a first operation \textcircled{1}, the main encoder 111a_2 may perform main ECC encoding on the write data DT_wr of N bits based on a first code (e.g., the LDPC code) to generate the main write parity data Dt_mwp of K bits.

In a second operation \textcircled{2}, the sub-data extractor 111a_1 may extract the first sub-write data DT_sw1 corresponding to a weak region of the write data DT_wr. The sub-data extractor 111a_1 may identify the position of the weak region WR based on the weak region information WR_info and may extract the first sub-write data DT_sw1.

In a third operation \textcircled{3}, the first sub-encoder 111a_4 may perform the first sub-ECC encoding on the first sub-write data DT_sw1 based on a second code (e.g., Hamming code). The first sub-encoder 111a_4 may perform the first sub-ECC encoding to generate the first sub-write parity data DT_swp1 of M bits corresponding to the first sub-write data DT_sw1. The first sub-write parity data DT_swp1 may include the first sub-parity bits for correcting an error of the first sub-write data DT_sw1.

In a fourth operation \textcircled{4}, the second sub-encoder 111a_5 may perform the second sub-ECC encoding on the first sub-write parity data based on a third code (e.g., Reed-Muller code). The second sub-encoder 111a_5 may perform the second sub-ECC encoding to generate the second sub-write parity data DT_swp2 of L bits. The second sub-write parity data DT_swp2 may include second sub-parity bits for correcting errors in the first sub-write parity data DT_swp1.

Referring to FIG. 6B, after the fourth operation \textcircled{4} is performed, the main codeword generator 111a_3 may combine the main write parity data DT_mwp and the write data DT_wr to generate the main write codeword CW_mw. In this case, the main write codeword CW_mw may include the write data DT_wr of N bits and the main write parity data Dt_mwp of K bits. In addition, the free-riding codeword generator 111a_6 may generate the write free-riding codeword CW_wf by combining the first sub-write parity data DT_swp1 and the second sub-write parity data DT_swp2. In this case, the write free-riding codeword CW_wf may include the first sub-write parity data DT_swp1 of M bits and the second sub-write parity data Dt_swp2 of L bits.

In a fifth operation \textcircled{5}, the write codeword generator 111a_7 may generate the write codeword CW_wr by superpositioning the write free-riding codeword CW_wf on the main write codeword CW_wm. In detail, the write codeword generator 111a_7 may generate the write codeword CW_wr by superpositioning the free-riding codeword CW_wf on a superposition position PS_sp of the main write codeword CW_wm. The write codeword generator 111a_7 may perform a bitwise XOR calculation on second sub-write data DT_sw2 of M+L bits included in the superposition position PS_sp of the main write codeword CW_wm and the write free-riding codeword CW_wf of M+L bits to superpose the write free-riding codeword CW_wf on the superposition position PS_sp of the main write codeword CW_mw.

In this case, the write codeword CW_wr may include a superposition region SPR including superposition data DT_ws. The superposition data DT_ws may include elements of the write free-riding codeword CW_wf and the second sub-write data DT_sw2.

In some implementations, the superposition position PS_sp may be included in the strong region SR. In some implementations, unlike that illustrated in FIG. 6A, the superposition position PS_sp may be a position that includes some bits of the write data DT_wr and some bits of the main write parity data DT_mwp. Meanwhile, the superposition region SPR may correspond to the superposition position PS_sp. Therefore, the superposition region SPR may be included in the strong region SR.

Referring to FIG. 6C, to generate the write codeword CW_wr, the write codeword generator 111a_7 may generate a calculation codeword CW_cal of the same size (i.e., N+K) bits as the main write codeword CW_wm. The calculation codeword CW_cal may include a write-free riding codeword CW_wf of M+L bits arranged at a position corresponding to the superposition position PS_sp of the main write codeword CW_wm and dummy data DT_dm of N-M+L+K bits having a bit value of “0”. The write codeword generator 111a_7 may generate the write codeword CW_wr by performing a bitwise XOR calculation on the main write codeword CW_wm and the calculation codeword CW_cal.

As described above, the ECC encoder 111a may generate the write codeword CW_wr by superpositioning the write free-riding codeword CW_wf including the first sub-write parity data for correcting an error of data (i.e., first sub-write data DT_sw1) in a weak region on the main write codeword CW_wm including the main write parity data DT_mwp. Accordingly, the write codeword CW_wr may include elements of the write data Dt_wr of N bits, the main write parity data Dt_mwp of K bits, and the first sub-write parity data Dt_swp1 of M bits. Therefore, the ECC encoder 111a may generate the write codeword CW_wr with enhanced protection for the write data DT_wr compared to the first write codeword CW_wr1 and the second write codeword CW_wr2 of FIG. 4.

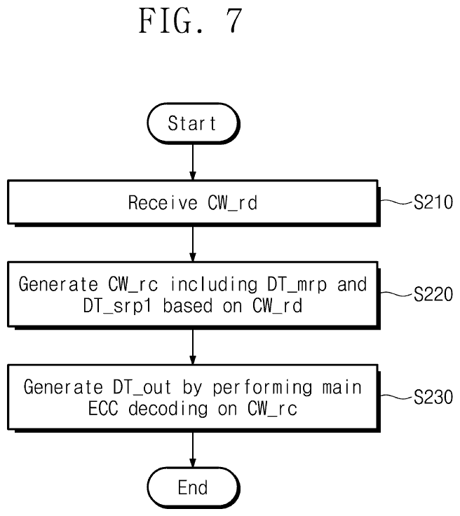

FIG. 7 is a flowchart for describing an example of an operation of an ECC decoder of FIG. 1. FIG. 7 is described with reference to FIG. 1, FIG. 2, and FIG. 5A to FIG. 6C. Referring to FIG. 7, in operation S210, the ECC decoder 111b may receive a read codeword CW_rd. For example, the read codeword CW_rd may be data received from the nonvolatile memory device 120 and stored in the buffer memory 113. The ECC decoder 111b may receive the read codeword CW_rd from the buffer memory 113.

In some implementations, the read codeword CW_rd may be data generated in a manner described with reference to FIG. 5A to FIG. 6C. In detail, the read codeword CW_rd may be data generated by superpositioning a read free-riding codeword including first sub-read parity data DT_srp1 and second sub-read parity data DT_srp2 on a read main codeword including a main read parity data DT_mrp. That is, for example, the read codeword CW_rd may correspond to data generated by the ECC encoder 111a and stored in the nonvolatile memory device 120.

In operation S220, the ECC decoder 111b may generate a reconstructed codeword CW_rc including the main read parity data DT_mrp and the first sub-read parity data DT_srp1 based on the read codeword CW_rd.

In operation S230, the ECC decoder 111b may perform main ECC decoding on the reconstructed codeword CW_rc to generate the output data DT_out. The ECC decoder 111b may perform the main ECC decoding based on the main read parity data DT_mrp and the first sub-read parity data DT_srp1 to correct an error in the reconstructed codeword CW_rc. The ECC decoder 111b may generate the output data DT_out composed of information bits of the corrected reconstructed codeword CW_rc. For example, the information bits may mean bits excluding parity bits in the corrected reconstructed codeword CW_rc. The ECC decoder 111b may transmit the output data DT_out to an external host.

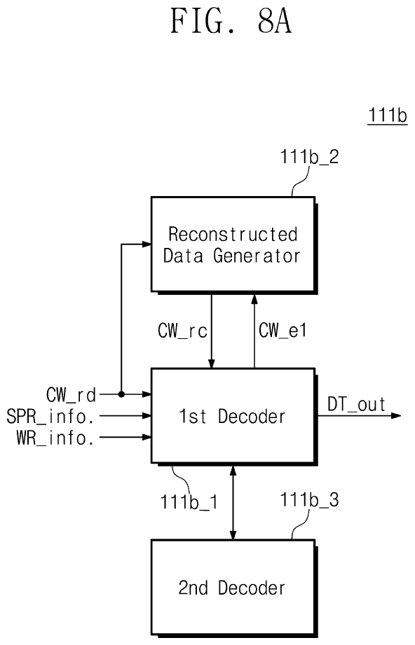

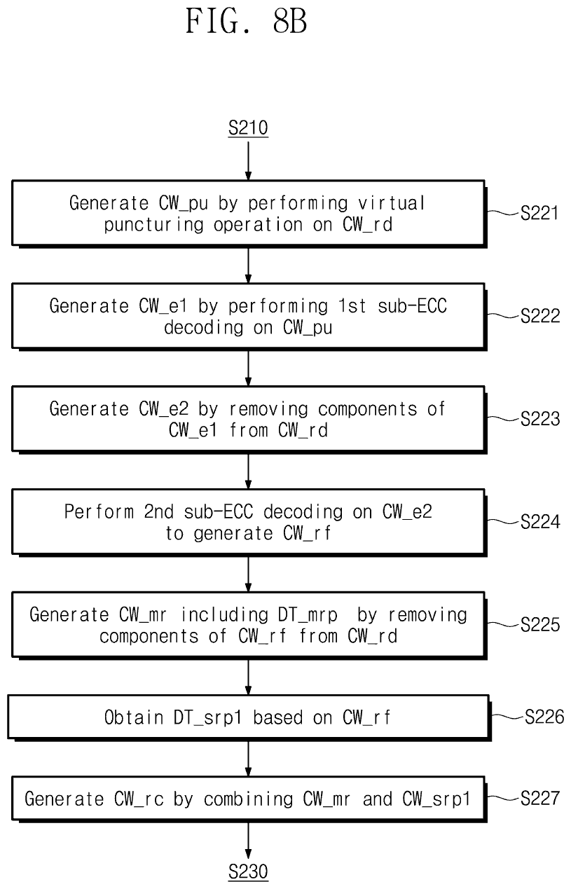

FIG. 8A is a block diagram illustrating an example of an ECC decoder of FIG. 1, and FIG. 8B is a flowchart for describing an example operation S220 of FIG. 7. Referring to FIG. 1 and FIG. 8A, the ECC decoder 111b may include a first decoder 111b_1, a reconstructed data generator 111b_2, and a second decoder 111b_3.

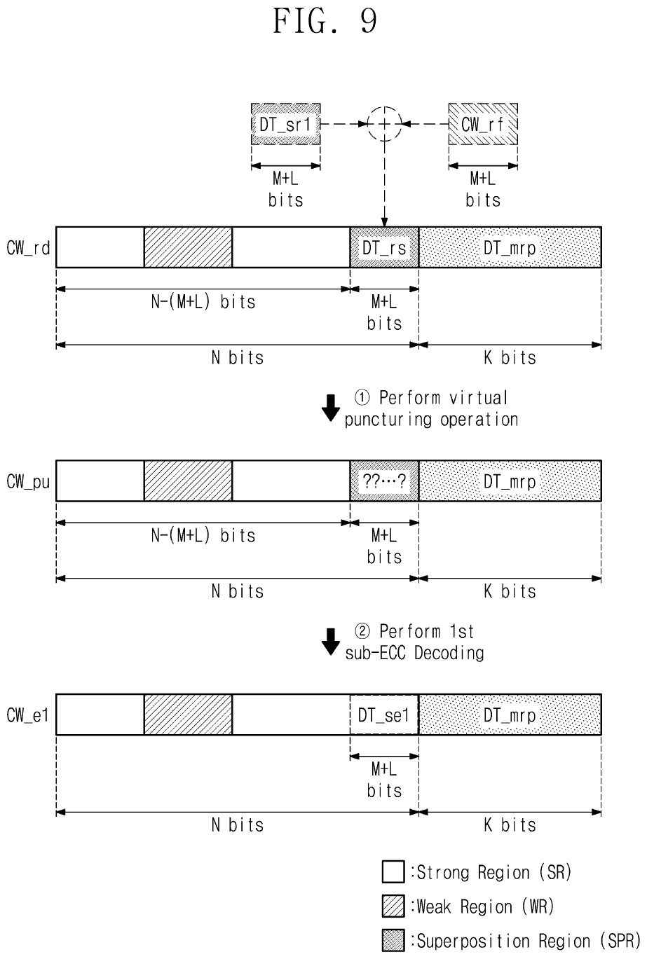

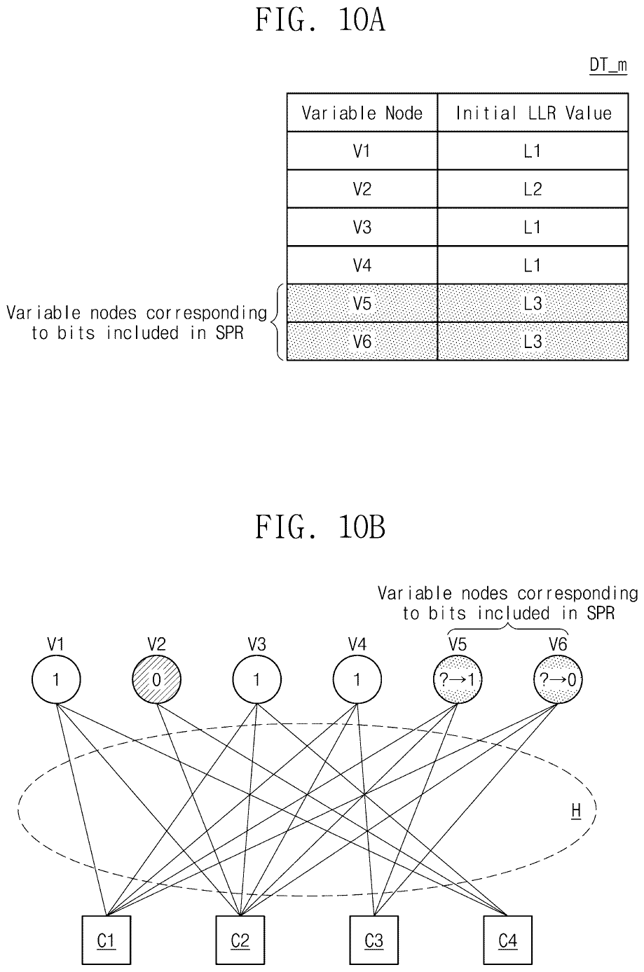

Referring to FIG. 8B, in operation S221, the ECC decoder 111b may perform a virtual puncturing operation on the read codeword CW_rd to generate a punctured codeword CW_pu. In some implementations, the virtual puncturing operation may mean an operation of processing bit values corresponding to bits of the superposition region SPR of the read codeword CW_rd as a first value. In some implementations, the first value may be an undefined value (i.e., an unknown value). In some implementations, the first value may be “0”. In some implementations, the first value may be “1”. The virtual puncturing operation is described in more detail with reference to FIGS. 9 to 10B.

For example, the first decoder 111b_1 may receive the read codeword CW_rd, the superposition region information SPR_info, and the weak region information WR_info. The first decoder 111b_1 may identify the position of the superposition region SPR (i.e., the superposition position) through the superposition region information SPR_info. The first decoder 111b_1 may perform the virtual puncturing operation on the read codeword CW_rd based on the position of the identified superposition region SPR to generate the punctured codeword CW_pu.

In operation S222, the ECC decoder 111b may perform first sub-ECC decoding on the punctured codeword CW_pu to generate the first estimated codeword CW_e1. For example, the first decoder 111b_1 may perform the first sub-ECC decoding based on a first code. The first code may be the same code used in the ECC encoder 111a when the main ECC encoding to generate the main read parity data Dt_mrp is performed. In some implementations, the first code may be an LDPC code. In some implementations, the first estimated codeword CW_e1 may include an estimation result for bit values of information bits corresponding to the superposition region SPR.

In operation S223, the ECC decoder 111b may generate a second estimated codeword CW_e2 by removing an element of the first estimated codeword CW_e1 from the read codeword CW_rd. In detail, the reconstructed data generator 111b_2 may generate the second estimated codeword CW_e2 by performing a bitwise XOR calculation on the read codeword CW_rd and the first estimated codeword CW_e1. In some implementations, the second estimated codeword CW_e2 may be an estimation result with respect to a read free-riding codeword CW_rf.

In operation S224, the ECC decoder 111b may perform the second sub-ECC decoding on the second estimated codeword CW_e2 based on a third code to generate the read free-riding codeword CW_rf. In some implementations, the third code may be the same code as the code used in the ECC encoder 111a when performing the second sub-ECC encoding to generate the second sub-read parity data DT_srp2. In some implementations, the third code may be a Reed-Muller code. For example, the reconstructed data generator 111b_2 may perform the second sub-ECC decoding to generate the read free-riding codeword CW_rf.

In operation S225, the ECC decoder 111b may generate a main read codeword CW_mr including the main read parity data DT_mrp by removing the element of the read free-riding codeword CW_rf from the read codeword CW_rd. For example, the reconstructed data generator 111b_2 may generate the main read codeword CW_mr by performing a bitwise XOR calculation based on the read codeword CW_rd and the read free-riding codeword CW_rf.

In operation S226, the ECC decoder 111b may obtain the first sub-read parity data DT_srp1 from the read free-riding codeword CW_rf. For example, the reconstructed data generator 111b_2 may extract the first sub-read parity data DT_srp1 from the read free-riding codeword CW_rf. The first sub-read parity data DT_srp1 may include first sub-read parity bits for correcting an error in the weak region WR of the read codeword CW_rd.

In operation S227, the ECC decoder 111b may generate the reconstructed codeword CW_rc by combining the main read codeword CW_mr and the first sub-read parity data DT_srp1. For example, the reconstructed data generator 111b_2 may generate the reconstructed codeword CW_rc by combining the first sub-read parity data DT_srp1 and the main read codeword CW_mr.

Referring back to FIG. 8A, the ECC decoder 111b may perform main ECC decoding on the reconstructed codeword CW_rc. The main ECC decoding may be performed by the first decoder 111b_1 and the second decoder 111b_3 based on the first code and the second code. In detail, the first decoder 111b_1 may correct errors in the reconstructed codeword CW_rc based on the main read parity data DT_mrp. The first decoder 111b_1 may perform ECC decoding on the reconstructed codeword CW_rc based on the first code (e.g., the LDPC code) to correct errors in the reconstructed codeword CW_rc. For example, the first decoder 111b_1 may identify the position of the weak region WR based on the weak region information WR_info. For example, the first decoder 111b_1 may transmit data included in the weak region WR of the reconstructed codeword CW_rc and the first sub-read parity data DT_srp1 to the second decoder 111b_3. The second decoder 111b_3 may correct an error in the data included in the weak region WR of the reconstructed codeword CW_rc based on the first sub-read parity data DT_srp1. The second decoder 111b_3 may perform ECC decoding based on the second code to correct an error in the weak region WR.

In some implementations, the second code may be the same code as the code used in the ECC encoder 111a when performing the first sub-ECC encoding to generate the first sub-read parity data DT_srp1. In some implementations, the second code may be a Hamming code.

The first decoder 111b_1 and the second decoder 111b_3 may verify each other's ECC decoding results. The first decoder 111b_1 and the second decoder 111b_3 may repeatedly perform ECC decoding based on the verified ECC decoding results to generate the corrected reconstructed codeword CW_rc. The first ECC decoder 111b_1 may output information bits of the corrected reconstructed codeword CW_rc as the output data DT_out. The information bits may be bits excluding parity bits (i.e., bits of the main read parity data DT_mrp and the first sub-read parity data DT_srp1) in the reconstructed codeword CW_rc.

In some implementations, the first decoder 111b_1 may perform the LDPC decoding based on the main read parity data DT_mrp to correct errors included in the information bits of the reconstructed codeword CW_rc. The first decoder 111b_1 may receive, from the second decoder 111b_3 while performing LDPC decoding, a result of performing Hamming code-based ECC decoding (e.g., performed based on the first sub-read parity data DT_srp1) on data included in the weak region WR of the reconstructed codeword CW_rc. The first decoder 111b_1 may modify the bit values of the information bits of the weak region WR of the reconstructed codeword CW_rc based on the result of performing ECC decoding received from the second decoder 111b_3. The first decoder 111b_1 may continue performing LDPC decoding based on the modified information bits. That is, the second decoder 111b_3 may perform main ECC decoding together with the first decoder 111b_1.

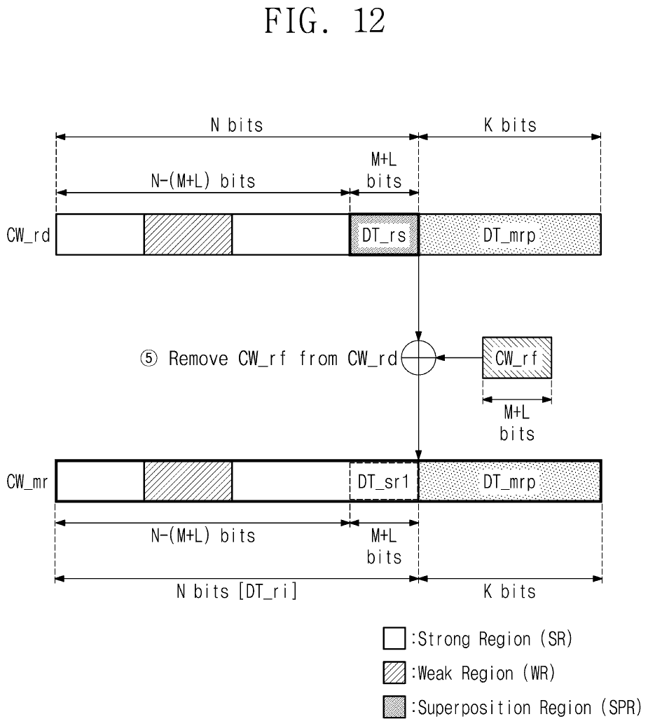

FIG. 9 is a diagram for describing example operations S221 and S222 of FIG. 8B. Referring to FIGS. 8A, 8B, and 9, the read codeword CW_rd of N+K bits may include the main read parity data DT_mrp composed of main parity bits of K bits. The read codeword CW_rd may be data generated by performing ECC encoding on read information data (DT_ri of FIG. 12) in the manner described with reference to FIGS. 5A to 6C. The read codeword CW_rd may include the weak region WR and the strong region SR, and may include the superposition region SPR in which the read free-riding codeword CW_rf superposes. In some implementations, the superposition region SPR may be included in the strong region SR.

The superposition region SPR may include superpositioned read data DT_rs of M+L bits. The superpositioned read data DT_rs may be data generated by superpositioning first sub-read data DT_sr1 composed of M+L bits of information bits and the read free-riding codeword CW_rf composed of M+L bits of sub-parity bits through ECC encoding. Therefore, the elements of the first sub-read data DT_sr1 and the elements of the read free-riding codeword CW_rf may be mixed and included in the superpositioned read data DT_rs.

In a first operation \textcircled{1}, the first ECC decoder 111b_1 may perform a virtual puncturing operation on the read codeword CW_rd. The first ECC decoder 111b_1 may perform a virtual puncturing operation to generate the punctured codeword CW_pu. The first ECC decoder 111b_1 may process the initial bit value corresponding to the bits of the superposition region SPR of the read codeword CW_rd (i.e., the bits of the superpositioned read data DT_rs) as a first value (e.g., an undefined value) through a virtual puncturing operation.

In a second operation \textcircled{2}, the first ECC decoder 111b_1 may perform the first sub-ECC decoding to generate the first estimated codeword CW_e1. In some implementations, the first sub-ECC decoding may mean ECC decoding based on a first code (e.g., the LDPC code) with respect to the punctured codeword CW_pu. The first decoder 111b_1 may perform the first sub-ECC decoding on the punctured codeword CW_pu in a manner similar to the manner described with reference to FIGS. 3A and 3B.

The first sub-ECC decoding may be an operation for correcting an error in the punctured codeword CW_pu based on the main read parity data DT_mrp. The punctured codeword CW_pu may not include an element of the read free-riding codeword CW_rf. Therefore, the first estimated codeword CW_e1 may be an estimation result with respect to the read codeword CW_rd from which the element of the read free-riding codeword CW_rf is removed. That is, the first ECC decoder 111b_1 may estimate the bit values of the information bits included in the superposition region SPR of the read codeword CW_rd through the virtual puncturing operation and the first sub-ECC decoding. In other words, first sub-estimation data DT_se1 of the first estimated codeword CW_e1 may be an estimation result with respect to the first sub-read data DT_sr1.

Meanwhile, as described above, the superposition region SPR may be included in the strong region SR. The strong region SR may have a higher error correction probability through the first sub-ECC decoding (e.g., the LDPC decoding) than the weak region WR. Accordingly, the first ECC decoder 111b_1 may accurately estimate bit values of information bits of the first sub-read data DT_sr1 by performing first sub-ECC decoding (e.g., LDPC decoding) on the punctured codeword CW_pu, compared to the case where the superposition region SPR is included in the weak region WR.

FIG. 10A and FIG. 10B are diagrams for describing an example of a virtual puncturing operation and an example of a first sub-ECC decoding of FIG. 9. FIG. 10A illustrates an example of mapping data DT_m generated based on the read codeword CW_rd. FIG. 10B is a diagram for describing the first sub-ECC decoding expressed as a tanner graph. Meanwhile, the examples of FIGS. 10A and 10B are described assuming that the first decoder 111b_1 performs hard decision-based LDPC decoding. However, the present disclosure is not limited thereto, and the first decoder 111b_1 may be configured to perform soft decision-based LDPC decoding.

Referring to FIGS. 8A, 9, and 10A, the first decoder 111b_1 may receive the read codeword CW_rd and the superposition region information SPR_info. The first decoder 111b_1 may perform the virtual puncturing operation on the read codeword CW_rd to generate the mapping data DT_m. The mapping data DT_m may include information on initial LLRs of the read codeword CW_rd. The mapping data DT_m may include information on initial LLRs corresponding to the punctured codeword CW_pu.

For example, the bit information of the read codeword CW_rd may be “101101”, and the bits corresponding to a fifth variable node V5 and a sixth variable node V6 may be bits included in the superposition region SPR. Therefore, the superpositioned read data DT_rs may be “01”.

In this case, the first decoder 111b_1 may set the initial LLR of the variable nodes V1, V3, and V4 to a first LLR value L1 corresponding to the bit value “1”. The first decoder 111b_1 may set the initial LLR of the second variable node V2 to a second LLR value L2 corresponding to the bit value “0” based on input data DT_rd. The second LLR value L2 may be a value having the same size as the first LLR value L1 and a different sign. The first decoder 111b_1 may set the initial LLR value of the variable nodes V5 and V6 to a third LLR value L3.

For example, the first LLR value L1 may be “−5”, the second LLR value L2 may be “5”, and the third LLR value L3 may be “0”. In this case, the initial bit values of the fifth variable node V5 and the sixth variable node V6 may be undefined values (i.e., unknown values). However, the present disclosure is not limited thereto, and in some implementations, the third LLR value L3 may mean a number (e.g., “−1”) having the same sign as the first LLR value L1 and a smaller size. In some implementations, the third LLR value L3 may mean a number (e.g., “1”) having the same sign as the second LLR value L2 and a smaller size.

Referring to FIG. 10B, the first decoder 111b_1 may store the initial LLR corresponding to the punctured codeword CW_pu in the variable nodes V1 to V6 based on the mapping data DT_m. That is, the first decoder 111b_1 may store the punctured codeword CW_pu in the variable nodes V1 to V6. That is, an LLR having the first LLR value L1 (e.g., “−5”) may be stored in the variable nodes V1, V3, and V4, an LLR having the second LLR value L2 (e.g., “5”) may be stored in the second variable node V2, and an LLR having the third LLR value L3 (e.g., “0”) may be stored in the fifth variable node V5 and the sixth variable node V6.

The LLR of a specific bit being “0” means that the probability that the bit may be “1” is the same as the probability that the bit may be “0”. Accordingly, the initial bit values of the fifth variable node V5 and the sixth variable node V6 may be undefined values (i.e., unknown values). In this case, the first decoder 111b_1 may modify the LLR of the fifth variable node V5 and the sixth variable node V6 through the first sub-ECC decoding. For example, the first sub-ECC decoding may be performed in the same manner as the LDPC decoding described with reference to FIGS. 3A and 3B.

In detail, the variable nodes V1 to V6 may transmit a variable node message including information about the LLR corresponding to the current variable nodes V1 to V6 to the check nodes C1 to C4. The check nodes C1 to C4 may determine whether the variable nodes connected to the check node satisfy an error detection rule based on the received LLR. The check nodes C1 to C4 may transmit check node messages containing information associated with whether the error detection rule is satisfied to the variable nodes V1 to V6. Through message exchange, the LLR of the variable nodes V1 to V6 may be modified. After multiple message exchanges between the variable nodes V1 to V6 and the check nodes C1 to C4 are performed, a final LLR of the variable nodes V1 to V6 may be determined. The first decoder 111b_1 may determine the bit values of the bits of the first estimated codeword CW_e1 based on the determined final LLR of the variable nodes V1 to V6. In the example of FIG. 10B, the first estimated codeword CW_e1 may be “101110”. Meanwhile, the first sub-estimation data DT_se1 may be “10”.

As described above, the first estimated codeword CW_e1 may be an estimation result associated with the read codeword CW_rd from which the element of the read free-riding codeword CW_rf is removed. Therefore, the bit information of the first estimated codeword CW_e1 may be different from the bit information of the read codeword CW_rd.

As described above, the first ECC decoder 111b_1 may perform a virtual puncturing operation on the read codeword CW_rd, and then may perform the first sub-ECC decoding to generate an estimation result (i.e., the first estimated codeword CW_e1 including the first sub-estimation data DT_se1) with respect to the first sub-read data DT_sr1.

Meanwhile, unlike the example described above, the first decoder 111b_1 may perform the LDPC decoding based on soft decision. In this case as well, the first decoder 111b_1 may set the absolute value of the initial LLR of the variable nodes (e.g., V5 and V6) corresponding to the bits included in the superposition region SPR to be less than the absolute value of the initial LLR of the variable nodes (e.g., V1 to V4) corresponding to bits other than the superposition region SPR through the virtual puncturing operation.

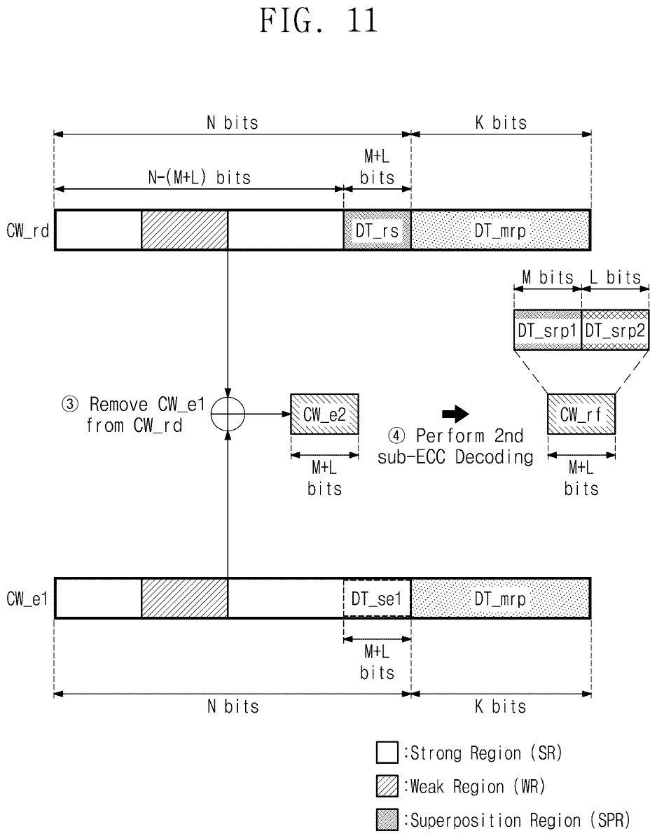

FIG. 11 is a diagram for describing example operations S223 and S224 of FIG. 8B. Referring to FIGS. 8A, 8B, and 11, in a third operation \textcircled{3}, the reconstructed data generator 111b_2 may remove an element of the first estimated codeword CW_e1 from the read codeword CW_rd. In detail, the reconstructed data generator 111b_2 may perform a bitwise XOR calculation on the first estimated codeword CW_e1 of N+K bits and the read codeword CW_rd of N+K bits.

The data on which the XOR calculation is performed may be the read codeword CW_rd from which the element of the first estimated codeword CW_e1 is removed. The data on which the XOR calculation is performed may include the second estimated codeword CW_e2. The second estimated codeword CW_e2 may be data of M+L bits included in a position corresponding to the superposition region SPR of the read codeword CW_rd in the data on which the XOR calculation is performed. That is, the second estimated codeword CW_e2 may be data from which the element of the first sub-estimated data DT_se1 is removed from the superpositioned read data DT_rs. As described above, the first sub-estimated data DT_se1 may mean an estimation result with respect to the first sub-read data DT_sr1. Therefore, the second estimated codeword CW_e2 may mean an estimation result with respect to the read free-riding codeword CW_rf.

In a fourth operation \textcircled{4}, the reconstructed data generator 111b_2 may perform the second sub-ECC decoding on the second estimated codeword CW_e2 to generate the read free-riding codeword CW_rf of M+L bits. The second sub-ECC decoding may be performed based on a third code (e.g., a Reed-Muller code). For example, the read free-riding codeword CW_rf may include the first sub-read parity data DT_srp1 composed of first sub-parity bits of M bits and the second sub-read parity data DT_srp2 composed of second sub-parity bits of L bits.

FIG. 12 is a diagram for describing an example operation S225 of FIG. 8B. Referring to FIGS. 8A, 8B, and 12, in a fifth operation \textcircled{5}, the reconstructed data generator 111b_2 may generate the main read codeword CW_mr by removing an element of the read free-riding codeword CW_rf from the read codeword CW_rd. In detail, the reconstructed data generator 111b_2 may generate a calculation codeword including the read free-riding codeword CW_rf in the region corresponding to a superposition region SPR, as described with respect to FIG. 6C, and having bit values of bits of the remaining regions as “0”. The reconstructed data generator 111b_2 may generate the main read codeword CW_mr by performing a bitwise XOR calculation on the calculation codeword and the read codeword CW_rd.

In detail, the reconstructed data generator 111b_2 may remove the element of the read free-riding codeword CW_rf from the superpositioned read data DT_rs through the bitwise XOR calculation. The main read codeword CW_mr may include the first sub-read data DT_sr1. The first sub-read data DT_sr1 may be data from which the element of the read free-riding codeword CW_rf is removed from the superpositioned read data DT_rs.

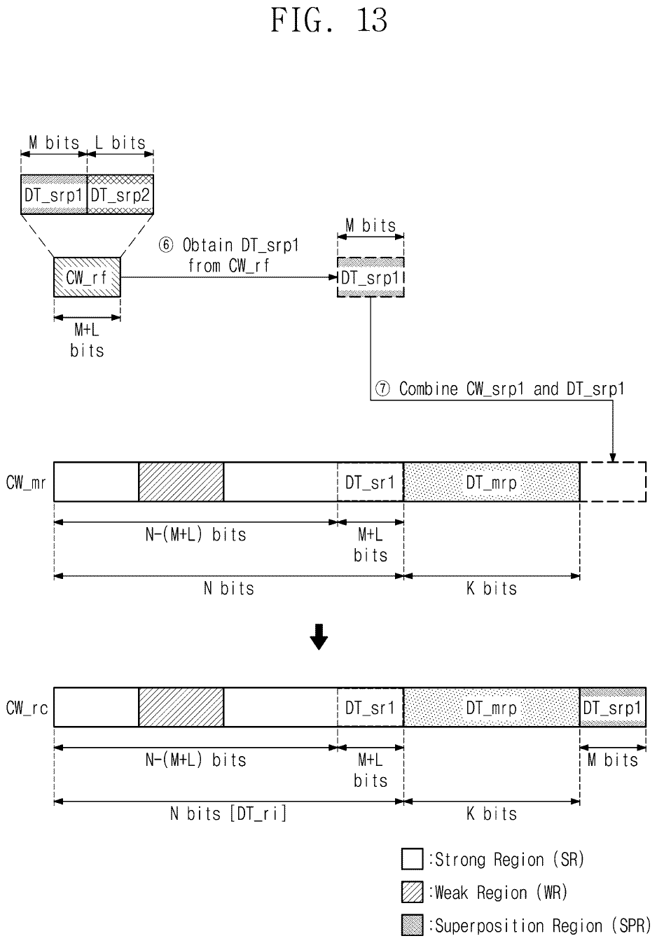

FIG. 13 is a diagram for describing example operations S226 and S227 of FIG. 8B. In a sixth operation \textcircled{6}, the reconstructed data generator 111b_2 may obtain the first sub-read parity data DT_srp1 of M bits from the read free-riding codeword CW_rf.

In some implementations, the read free-riding codeword CW_rf may be a systematic codeword. In this case, the reconstructed data generator 111b_2 may extract the information bits of the read free-riding codeword CW_rf as the first sub-read parity data DT_srp1.

In some implementations, the read free-riding codeword CW_rf may be a nonsystematic codeword. In this case, the read free-riding codeword CW_rf may be configured in a form in which the bits of the first sub-read parity data DT_srp1 and the bits of the second sub-read parity data DT_srp2 are not distinguished. In this case, the reconstructed data generator 111b_2 may perform a demapping operation to extract the first sub-read parity data DT_srp1 from the read free-riding codeword CW_rf to obtain the first sub-read parity data DT_srp1.

In a seventh operation \textcircled{7}, the reconstructed data generator 111b_2 may generate the reconstructed codeword CW_rc by combining the main read codeword CW_mr and the first sub-read parity data DT_srp1. The reconstructed codeword CW_rc may include the read information data DT_ri, the main read parity data DT_mrp, and the first sub-read parity data DT_srp1. The read information data DT_ri may be composed of N bits of information bits. The main read parity data DT_mrp may be composed of K bits of main parity bits for performing ECC decoding based on a first code (e.g., an LDPC code). The first sub-read parity data DT_srp1 may be composed of M bits of first sub-parity bits for performing ECC decoding based on a second code (e.g., a Hamming code).

The first decoder 111b_1 and the second decoder 111b_3 may perform main ECC decoding based on the first code (e.g., the LDPC code) and the second code (e.g., the Hamming code) based on the reconstructed codeword CW_rc to generate the corrected reconstructed codeword CW_rc. The first decoder 111b_1 may generate the output data DT_out composed of information bits of the corrected reconstructed codeword CW_rc.

As described above, the ECC decoder 111b may generate the reconstructed codeword CW_rc including the parity bits of M+K bits based on the read codeword CW_rd of N+K bits. Accordingly, the error correction capability of the ECC decoder 111b may be improved.

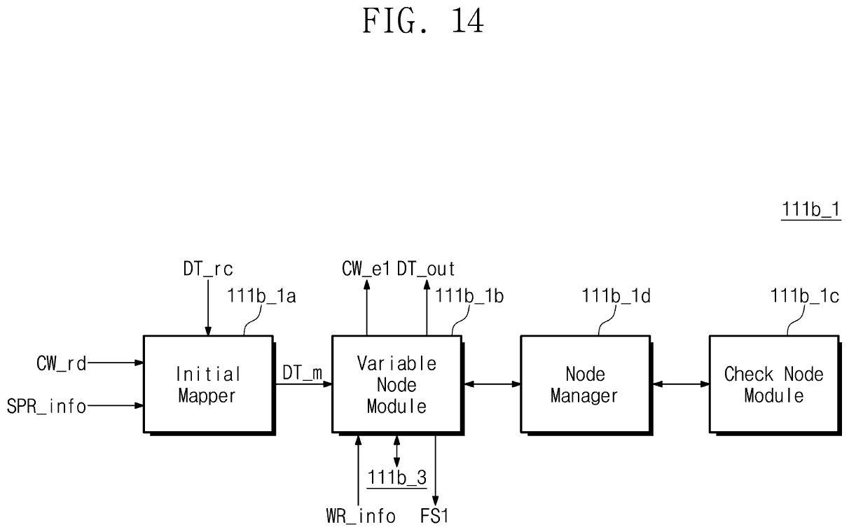

FIG. 14 is a block diagram illustrating an example of a first decoder of FIG. 8A. Referring to FIGS. 8A to 14, the first decoder 111b_1 may include an initial mapper 111b_1a, a variable node module 111b_1b, a check node module 111b_1c, and a node manager 111b_1d.

The initial mapper 111b_1a may receive the read codeword CW_rd, the superposition region information SPR_info, and the reconstructed codeword CW_rc. The initial mapper 111b_1a may generate the mapping data DT_m including information of initial LLRs corresponding to the read codeword CW_rd or the reconstructed codeword CW_rc. The initial mapper 111b_1a may transmit the mapping data DT_m to the variable node module 111b_1b.

For example, when the read codeword CW_rd and superposition region information SPR_info are received, the initial mapper 111b_1a may perform the virtual puncturing operation to generate the mapping data DT_m. The mapping data DT_m may include initial LLR information corresponding to the punctured codeword CW_pu. That is, the initial mapper 111b_1a may generate the punctured codeword CW_pu by performing the virtual puncturing operation to generate the mapping data DT_m.

For example, when the reconstructed codeword Cw_rc is received, the initial mapper 111b_1a may generate the mapping data DT_m corresponding to the reconstructed codeword CW_rc. The mapping data may include the initial LLR information corresponding to the reconstructed codeword CW_rc.

The variable node module 111b_1b may include a plurality of variable nodes. The variable node module 111b_1b may store an LLR corresponding to each of the variable nodes. In this case, the variable node module 111b_1b may identify the initial LLR corresponding to each of the variable nodes based on the mapping data DT_m. The variable node module 111b_1b may transmit variable node messages to the check node module 111b_1c through the node manager 111b_1d. The variable node messages may include information about the bit value (i.e., the LLR) of the corresponding variable node.

In some implementations, the first decoder 111b_1 and the second decoder 111b_3 may perform main ECC decoding on the reconstructed codeword CW_rc. In this case, the variable node module 111b_1b may identify the data included in the weak region WR of the reconstructed codeword CW_rc corresponding to the mapping data DT_m and the first sub-read parity data DT_srp1 based on the weak region information WR_info. The variable node module 111b_1b may transmit the data included in the weak region WR and the first sub-read parity data DT_srp1 to the second decoder 111b_3.

The check node module 111b_1c may include a plurality of check nodes. The check nodes may determine whether the bit values of the corresponding variable nodes satisfy the error detection rule. The check node module 111b_1c may transmit check node messages to the variable node module 111b_1b through the node manager 111b_1d. The check node message may include information about whether the variable nodes corresponding to the check node satisfy the error detection rule.

The node manager 111b_1d may perform message transmission between the variable nodes and the check nodes. For example, the node manager 111b_1d may transmit the variable node message to the check node module 111b_1c. The node manager 111b_1d may receive the check node message from the check node module 111b_1c. The node manager 111b_1d may change the current LLR values of the variable nodes based on the check node message. The node manager 111b_1d may adjust the LLR of each variable node by repeating the transmission of the variable node message and the check node message. The node manager 111b_1d may determine the LLR of each variable node as a final LLR after the message transmission is repeated a critical number of times.

For example, the first decoder 111b_1 may perform the first sub-ECC decoding. In this case, message exchange between the variable nodes and the check nodes may be performed based on the mapping data DT_m corresponding to the punctured codeword CW_pu. In addition, the variable node module 111b_1b may output data corresponding to the final LLR of the variable nodes as the first estimated codeword CW_e1.

For example, the first decoder 111b_1 and the second decoder 111b_3 may perform the main ECC decoding on the reconstructed codeword CW_rc. In this case, message exchange between the variable nodes and the check nodes may be performed based on the mapping data DT_m corresponding to the reconstructed codeword CW_rc and the ECC decoding result from the second decoder 111b_3. In this case, the variable node module 111b_1b may output the output data DT_out composed of information bits excluding parity bits from the codeword (e.g., the corrected reconstructed codeword Cw_rc) corresponding to the final LLR of the variable nodes.

In some implementations, the variable node module 111b_1b may determine whether there is an error in first estimated data DT_e1 and the output data DT_out. In some implementations, the variable node module 111b_1b may output a first decoding failure signal FS1 when the number of errors in the first estimated codeword CW_e1 is greater than or equal to a predetermined threshold number. In some implementations, the variable node module 111b_1b may output the first decoding failure signal FS1 when there is an error in the output data DT_out.

In some implementations, the storage controller 110 may, in response to the first decoding failure signal FS1, determine that ECC decoding for the read codeword CW_rd is failed, and then may transmit a retransmission command requesting retransmission of the read codeword CW_rd to the nonvolatile memory device 120.

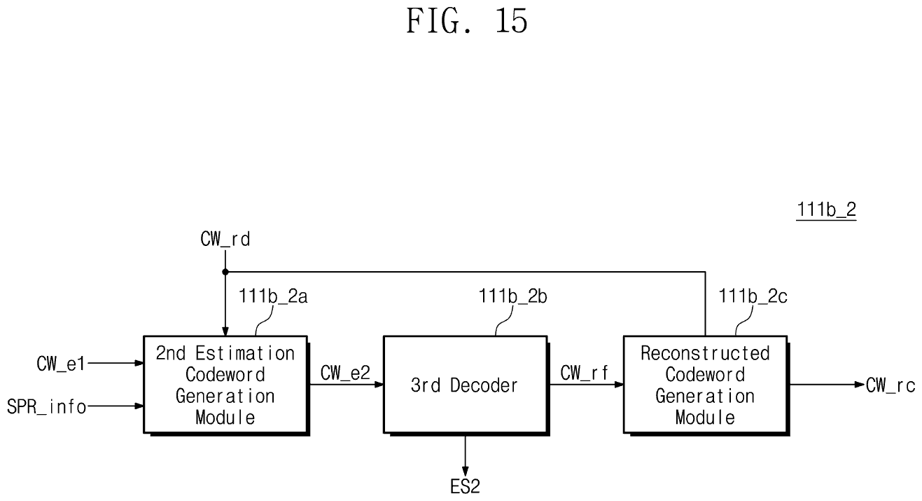

FIG. 15 is a block diagram illustrating an example of a reconstructed codeword generator of FIG. 8A. FIG. 15 is described with reference to FIG. 8A to FIG. 14. Referring to FIG. 15, a reconstructed codeword generator 111b_2 may include a second estimation codeword generation module 111b_2a, a third decoder 111b_2b, and a reconstructed codeword generation module 111b_2c.

The second estimation codeword generation module 111b_2a may receive the first estimated codeword CW_e1, the superposition region information SPR_info and the read codeword CW_rd. The second estimation codeword generation module 111b_2a may generate the second estimated codeword CW_e2. The second estimation codeword generation module 111b_2a may perform a bitwise XOR calculation on the read codeword CW_rd and the first estimated codeword CW_e1. The codeword on which the XOR calculation is performed may be a codeword from which the element of the first estimated codeword CW_e1 is removed from the read codeword CW_rd. The second estimation codeword generation module 111b_2a may identify the position of the superposition region based on the superposition region information SPR_info. The second estimation codeword generation module 111b_2a may output the bits included in the position of the superposition region in the codeword on which the XOR calculation is performed as the second estimated codeword CW_e2.

The third decoder 111b_2b may perform the second sub-ECC decoding on the second estimated codeword CW_e2 based on the third code (e.g., the Reed-Muller code). The third decoder 111b_2b may perform the second sub-ECC decoding to generate the read free-riding codeword CW_rf.

The reconstructed codeword generation module 111b_2c may receive the read free-riding codeword CW_rf and the read codeword CW_rd. The reconstructed codeword generation module 111b_2c may generate the main read codeword CW_mr by removing the element of the read free-riding codeword CW_rf from the read codeword CW_rd. The reconstructed codeword generation module 111b_2c may obtain the first sub-read parity data DT_srp1 from the read free-riding codeword CW_rf. The reconstructed codeword generation module 111b_2c may generate the reconstructed codeword CW_rc by combining the main read codeword CW_mr and the first sub-read parity data DT_srp1. The reconstructed codeword generation module 111b_2c may transmit the reconstructed codeword CW_rc to the first decoder 111b_1.

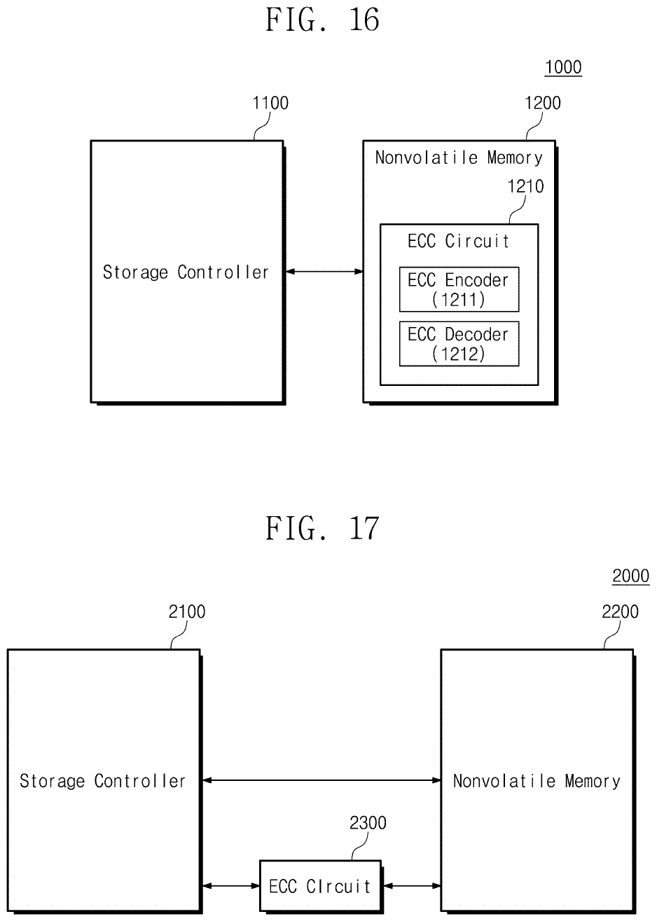

FIG. 16 is a block diagram illustrating an example of a storage device. Referring to FIG. 16, a storage device 1000 may include a storage controller 1100 and a nonvolatile memory device 1200. The storage controller 1100 may store data into the nonvolatile memory device 1200 or may read data stored in the nonvolatile memory device 1200. In some implementations, the nonvolatile memory device 1200 may include an ECC circuit 1210. The ECC circuit 1210 may include an ECC encoder 1211 and an ECC decoder 1212.

In some implementations, the ECC encoder 1211 may perform ECC encoding based on the operating method described with reference to FIGS. 5A to 6C. The ECC encoder 1211 may perform the sub-ECC encoding on data included in a weak region of data transmitted from the storage controller 1100 to generate a free-riding codeword including sub-parity data. The ECC encoder 1211 may generate a write codeword by superpositioning the free-riding codeword on a main codeword including main parity data. The nonvolatile memory device 1200 may store the generated write codeword.

In some implementations, the ECC decoder 1212 may perform the ECC decoding based on the operating method described with reference to FIGS. 7 to 15. The ECC decoder 1212 may obtain a main codeword including sub-parity data and main parity data from the read codeword stored in the nonvolatile memory device 1200, and may generate a reconstructed codeword by combining the main codeword and the sub-parity data. The ECC decoder 1212 may perform ECC decoding on the reconstructed codeword to correct an error in the reconstructed codeword. The nonvolatile memory device 1200 may transmit information bits of the error-corrected reconstructed codeword to the storage controller 1100 as output data.

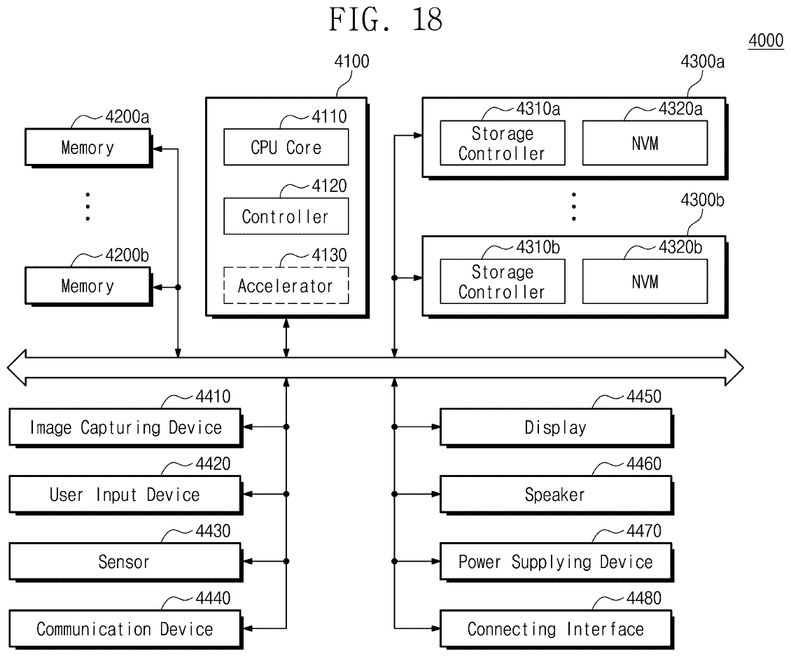

FIG. 17 is a block diagram illustrating an example of a storage device. Referring to FIG. 17, a storage device 2000 may include a storage controller 2100, a nonvolatile memory device 2200, and an ECC circuit 2300. The storage controller 2100 may store data into the nonvolatile memory device 2200 or may read data stored in the nonvolatile memory device 2200. In some implementations, the ECC circuit 2300 may be located in a data path between the storage controller 2100 and the memory device 2200. The ECC circuit 2300 may be configured to correct errors in data transmitted and received between the storage controller 2100 and the memory device 2200. In some implementations, the ECC circuit 2300 may perform ECC encoding and ECC decoding based on the operating method described with reference to FIGS. 5A to 15. The ECC circuit 2300 may perform ECC encoding by superpositioning the free-riding codeword including the sub-parity data on the main data. The ECC circuit 2300 may reconstruct received data to generate reconstructed data including information bits, main parity data, and sub-parity data. The ECC circuit 2300 may perform ECC decoding on the reconstructed data to correct errors in the reconstructed data.

FIG. 18 is a diagram of an example of a system 4000 to which a storage device is applied. The system 4000 of FIG. 18 may basically be a mobile system, such as a portable communication terminal (e.g., a mobile phone), a smartphone, a tablet personal computer (PC), a wearable device, a healthcare device, or an Internet of things (IOT) device. However, the system 4000 of FIG. 18 is not necessarily limited to the mobile system and may be a PC, a laptop computer, a server, a media player, or an automotive device (e.g., a navigation device).

Referring to FIG. 18, the system 4000 may include a main processor 4100, memories (e.g., 4200a and 4200b), and storage devices (e.g., 4300a and 4300b). In addition, the system 4000 may include at least one of an image capturing device 4410, a user input device 4420, a sensor 4430, a communication device 4440, a display 4450, a speaker 4460, a power supplying device 4470, and a connecting interface 4480.

The main processor 4100 may control all operations of the system 4000, more specifically, operations of other components included in the system 4000. The main processor 4100 may be implemented as a general-purpose processor, a dedicated processor, or an application processor.

The main processor 4100 may include at least one CPU core 4110 and further include a controller 4120 configured to control the memories 4200a and 4200b and/or the storage devices 4300a and 4300b. In some implementations, the main processor 4100 may further include an accelerator 4130, which is a dedicated circuit for a high-speed data operation, such as an artificial intelligence (AI) data operation. The accelerator 4130 may include a graphics processing unit (GPU), a neural processing unit (NPU) and/or a data processing unit (DPU) and be implemented as a chip that is physically separate from the other components of the main processor 4100.

The memories 4200a and 4200b may be used as main memory devices of the system 4000. Although each of the memories 4200a and 4200b may include a volatile memory, such as static random access memory (SRAM) and/or dynamic RAM (DRAM), each of the memories 4200a and 4200b may include non-volatile memory, such as a flash memory, phase-change RAM (PRAM) and/or resistive RAM (RRAM). The memories 4200a and 4200b may be implemented in the same package as the main processor 4100.

The storage devices 4300a and 4300b may serve as non-volatile storage devices configured to store data regardless of whether power is supplied thereto, and have larger storage capacity than the memories 4200a and 4200b. The storage devices 4300a and 4300b may respectively include storage controllers(STRG CTRL) 4310a and 4310b and NVM(Non-Volatile Memory)s 4320a and 4320b configured to store data via the control of the storage controllers 4310a and 4310b. Although the NVMs 4320a and 4320b may include flash memories having a two-dimensional (2D) structure or a three-dimensional (3D) V-NAND structure, the NVMs 4320a and 4320b may include other types of NVMs, such as PRAM and/or RRAM.

The storage devices 4300a and 4300b may be physically separated from the main processor 4100 and included in the system 4000 or implemented in the same package as the main processor 4100. In addition, the storage devices 4300a and 4300b may have types of solid-state devices (SSDs) or memory cards and be removably combined with other components of the system 4000 through an interface, such as the connecting interface 4480 that will be described below. The storage devices 4300a and 4300b may be devices to which a standard protocol, such as a universal flash storage (UFS), an embedded multi-media card (eMMC), or a non-volatile memory express (NVMe), is applied, without being limited thereto.

The image capturing device 4410 may capture still images or moving images. The image capturing device 4410 may include a camera, a camcorder, and/or a webcam.

The user input device 4420 may receive various types of data input by a user of the system 4000 and include a touch pad, a keypad, a keyboard, a mouse, and/or a microphone.

The sensor 4430 may detect various types of physical quantities, which may be obtained from the outside of the system 4000, and convert the detected physical quantities into electric signals. The sensor 4430 may include a temperature sensor, a pressure sensor, an illuminance sensor, a position sensor, an acceleration sensor, a biosensor, and/or a gyroscope sensor.

The communication device 4440 may transmit and receive signals between other devices outside the system 4000 according to various communication protocols. The communication device 4440 may include an antenna, a transceiver, and/or a modem.

The display 4450 and the speaker 4460 may serve as output devices configured to respectively output visual information and auditory information to the user of the system 4000.

The power supplying device 4470 may appropriately convert power supplied from a battery embedded in the system 4000 and/or an external power source, and supply the converted power to each of components of the system 4000.

The connecting interface 4480 may provide connection between the system 4000 and an external device, which is connected to the system 4000 and capable of transmitting and receiving data to and from the system 4000. The connecting interface 4480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

According to some implementations of the present disclosure, the ECC circuit may include an ECC encoder and an ECC decoder. The ECC encoder may generate a write codeword by superpositioning parity data on a main write codeword. The ECC decoder may decode a read codeword to generate a reconstructed codeword. The reconstructed codeword may include sub-parity data superpositioned on a superposition region of a read codeword, and main parity data included in the read codeword. The ECC decoder may correct an error of the reconstructed codeword based on the sub-parity data and the main parity data. Accordingly, an ECC circuit having improved reliability, an operation method of the ECC circuit, and a storage controller including the ECC circuit may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above descriptions are detail implementations for carrying out the present disclosure. Implementations in which a design is changed simply or which are easily changed may be included in the present disclosure as well as an implementation described above. In addition, technologies that are easily changed and implemented by using the above implementations may be included in the present disclosure. Therefore, the scope of the present disclosure should not be limited to the above-described implementations and should be defined by not only the claims to be described later, but also those equivalent to the claims of the present disclosure.

What is claimed is:

1. An error correction code (ECC) circuit comprising an ECC decoder, wherein the ECC decoder comprises:
a first decoder configured to
perform a virtual puncturing operation for setting an initial bit value of bits of a superposition region in a read codeword to a first value to generate a punctured codeword, the read codeword being received from an external device, and
perform first sub-ECC decoding on the punctured codeword to generate a first estimated codeword;
a reconstructed data generator configured to
generate, based on the read codeword and the first estimated codeword, a second estimated codeword corresponding to the superposition region, and
generate, based on the read codeword and the second estimated codeword, a reconstructed codeword, the reconstructed codeword including read information data, main parity data, and first sub-parity data; and
a second decoder, wherein the first decoder and the second decoder are configured to perform main ECC decoding on the reconstructed codeword to correct an error in the reconstructed codeword.

2. The ECC circuit of claim 1, wherein a number of bits of the reconstructed codeword is greater than a number of bits of the read codeword.

3. The ECC circuit of claim 1, wherein the read codeword is generated based on superpositioning a read free-riding codeword on a main read codeword, the read free-riding codeword including the first sub-parity data, and the main read codeword including the read information data.

4. The ECC circuit of claim 1, wherein the first decoder is configured to perform the virtual puncturing operation by setting an initial log-likelihood ratio (LLR) of the bits of the superposition region to a first LLR value, and by setting an initial LLR of bits of the read codeword other than the bits of the superposition region to a second LLR value, the second LLR value being different from the first LLR value.

5. The ECC circuit of claim 4, wherein the first LLR value is less than an absolute value of the initial LLR of the bits of the read codeword other than the bits of the superposition region.

6. The ECC circuit of claim 1, wherein the reconstructed data generator is configured to
perform second sub-ECC decoding on second estimated data to obtain a read free-riding codeword, the read free-riding codeword including the first sub-parity data and second sub-parity data;
generate, based on the read codeword and the read free-riding codeword, a main read codeword, the main read codeword including the read information data and the main parity data;
obtain the first sub-parity data based on the read free-riding codeword; and
generate the reconstructed codeword based on combining the main read codeword and the first sub-parity data.

7. The ECC circuit of claim 6, wherein the ECC decoder is configured to
perform the first sub-ECC decoding based on a first code,
perform the second sub-ECC decoding based on a second code, and
perform the main ECC decoding based on the first code and a third code.

8. The ECC circuit of claim 7, wherein each code of the first code, the second code, and the third code is a low density parity check (LDPC) code, a Reed-Muller code, or a Hamming code.

9. The ECC circuit of claim 1, wherein the read codeword includes a first region and a second region, the first region having a first probability of error correction success through ECC decoding based on the main parity data, the second region having a second probability of error correction success, the first probability being higher than the second probability, and
wherein the first region includes the superposition region.

10. The ECC circuit of claim 9, wherein the first sub-parity data includes a plurality of first sub-parity bits corresponding to the second region.

11. The ECC circuit of claim 1, wherein the ECC circuit comprises an ECC encoder, and wherein the ECC encoder includes:
a main encoder configured to perform main ECC encoding on write data to generate main write parity data, the write data being received from the external device;
a first sub-encoder configured to perform first sub-ECC encoding on sub-write data to generate first sub-write parity data, the sub-write data being in the write data;
a second sub-encoder configured to perform second sub-ECC encoding on the first sub-write parity data to generate second sub-write parity data; and
a write codeword generator configured to generate a write codeword based on superpositioning a write free-riding codeword on a main write codeword, the write free-riding codeword including the first sub-write parity data and the second sub-write parity data, and the main write codeword being generated based on the main write parity data and the write data.

12. The ECC circuit of claim 11, wherein the write data includes a first region and a second region, the first region having a first probability of error correction success through ECC decoding based on the main write parity data, the second region having a second probability of the error correction success, and the first probability being higher than the second probability, and
wherein the second region includes the sub-write data.

13. The ECC circuit of claim 12, wherein the write codeword generator is configured to generate the write data based on superpositioning the write free-riding codeword on the first region.

14. A storage controller comprising an error correction code (ECC) circuit, wherein the ECC circuit comprises an ECC decoder including a first decoder and a reconstructed data generator, and wherein the first decoder is configured to:
perform a virtual puncturing operation for setting an initial log-likelihood ratio (LLR) to a first LLR value to generate a virtual punctured codeword, the initial LLR corresponding to information bits included in a superposition region of a read codeword that is received from a nonvolatile memory device; and
perform first sub-ECC decoding on the virtual punctured codeword to generate a first estimated codeword, and
wherein the reconstructed data generator is configured to
generate a second estimated codeword based on removing an element of the first estimated codeword from the read codeword;
perform second sub-ECC decoding on the second estimated codeword to generate a read free-riding codeword;
generate a main read codeword based on removing an element of the read free-riding codeword from the read codeword, the main read codeword including main read parity data;
obtain first sub-read parity data based on the read free-riding codeword; and
generate a reconstructed codeword based on combining the main read codeword and the first sub-read parity data.

15. The storage controller of claim 14, wherein the ECC decoder includes a second decoder, and the first decoder and the second decoder are configured to perform main ECC decoding on the reconstructed codeword to correct an error in the reconstructed codeword.

16. The storage controller of claim 14, wherein a number of bits of the reconstructed codeword is greater than a number of bits of the read codeword.

17. The storage controller of claim 14, wherein the first LLR value is less than an absolute value of an initial LLR of bits having a first bit value or a second bit value.

18. The storage controller of claim 14, wherein the ECC circuit includes an ECC encoder, and wherein the ECC encoder includes:
a main encoder configured to perform main ECC encoding on write data to generate main write parity data, the write data being received from an external host;
a first sub-encoder configured to perform first sub-ECC encoding on sub-write data to generate first sub-write parity data, the sub-write data being included in the write data;
a second sub-encoder configured to perform second sub-ECC encoding on the first sub-write parity data to generate second sub-write parity data; and
a write codeword generator configured to generate a write codeword based on superpositioning a write free-riding codeword on a main write codeword, the write free-riding codeword including the first sub-write parity data and the second sub-write parity data, the main write codeword being generated based on the main write parity data and the write data.

19. The storage controller of claim 18, wherein the write data includes a first region and a second region, the first region having a first probability of error correction success through ECC decoding based on the main write parity data, the second region having a second probability of the error correction success, the first probability being higher than the second probability,
wherein the second region includes the sub-write data, and
wherein the ECC encoder is configured to generate the write data based on superpositioning the write free-riding codeword on the first region.

20. An operation method of an error correction code (ECC) circuit comprising an ECC decoder, the method comprising:
receiving, by the ECC decoder, a read codeword;
performing, by the ECC decoder, a virtual puncturing operation to set an initial log-likelihood ratio (LLR) to a first LLR value to generate a virtual punctured codeword, the initial LLR corresponding to a superposition region included in the read codeword;
performing, by the ECC decoder, first sub-ECC decoding on the virtual punctured codeword to generate a first estimated codeword;
generating, by the ECC decoder based on the read codeword and the first estimated codeword, a second estimated codeword;
performing, by the ECC decoder, second sub-ECC decoding on the second estimated codeword to obtain a read free-riding codeword;
generating, by the ECC decoder based on the read codeword and the read free-riding codeword, a main read codeword, the main read codeword including main read parity data;
obtaining, by the ECC decoder, a first sub-read parity data based on the read free-riding codeword; and
generating, by the ECC decoder, a reconstructed codeword based on combining the main read codeword and the first sub-read parity data.
